(19) United States
(12) Patent Application Publication
(10) Pub. No.: US 2025/0194076 A1
(43) Pub. Date: Jun. 12, 2025

(54) SEMICONDUCTOR DEVICES

(71) Applicant: Samsung Electronics Co., Ltd., Suwon-si (KR)

(72) Inventor: Hyungki Cho, Suwon-si (KR)

(21) Appl. No.: 18/942,862

(22) Filed: Nov. 11, 2024

(30) Foreign Application Priority Data
Dec. 7, 2023 (KR) 10-2023-0176774

(51) Int. Cl. H10B 12/00

(52) U.S. Cl. CPC H10B 12/315; H10B 12/05

(57) ABSTRACT

A semiconductor device includes a bit line disposed on a substrate and extending in a first horizontal direction, a word line disposed at a higher vertical level above a top surface of the substrate than the bit line and extending in a second horizontal direction crossing the first horizontal direction, a channel layer extending in a vertical direction on a side wall of the word line and including a first side wall facing the word line and a second side wall opposite to the first side wall, a first capping liner disposed on the second side wall of the channel layer and including silicon nitride, and a first buried insulating layer disposed on a side wall of the first capping liner.

### CROSS-REFERENCE TO RELATED APPLICATION

This application is based on and claims priority under 35 U.S.C. § 119 to Korean Patent Application No. 10-2023-0176774, filed on Dec. 7, 2023, in the Korean Intellectual Property Office, the disclosure of which is incorporated by reference herein in its entirety.

### BACKGROUND

The inventive concept relates to a semiconductor device, and more particularly, to a semiconductor device including a vertical channel transistor.

With the downscaling of semiconductor devices, the size of dynamic random access memory (DRAM) devices is also reduced. In a DRAM device having a 1T-1C structure in which one capacitor is connected to one transistor, there is a limitation that the smaller the device becomes, the more current leakage through a channel region increases. To reduce current leakage, vertical channel transistors are proposed which use oxide semiconductor materials as a channel layer.

### SUMMARY

Aspects of the inventive concept provide a semiconductor device having improved electrical performance.

According to an aspect of the inventive concept, a semiconductor device includes a bit line located above a substrate and extending in a first horizontal direction, a word line located at a higher vertical level above a top surface of the substrate than the bit line and extending in a second horizontal direction crossing the first horizontal direction, a channel layer extending in a vertical direction on a side wall of the word line and including a first side wall facing the word line and a second side wall opposite to the first side wall, a first capping liner located on the second side wall of the channel layer and including silicon nitride or a high-k dielectric material, and a first buried insulating layer located on a side wall of the first capping liner.

According to another aspect of the inventive concept, a semiconductor device includes a bit line located above a substrate and extending in a first horizontal direction, a word line located at a higher vertical level above a top surface of the substrate than the bit line and extending in a second horizontal direction crossing the first horizontal direction, a gate insulating layer located on a side wall of the word line, a channel layer extending in a vertical direction on a side wall of the gate insulating layer and including a first side wall facing the gate insulating layer, a second side wall opposite to the first side wall, and a third side wall and a fourth side wall spaced apart from each other in the second horizontal direction, a first capping liner located on the second side wall of the channel layer and including silicon nitride or a high-k dielectric material, and a second capping liner located on the third side wall and the fourth side wall of the channel layer and including silicon nitride or a high-k dielectric material.

According to another aspect of the inventive concept, a semiconductor device includes a peripheral circuit region located above a substrate, a bit line located in the peripheral circuit region and extending in a first horizontal direction, a word line located at a higher vertical level above a top surface of the substrate than the bit line and extending in a second horizontal direction crossing the first horizontal direction, a channel layer extending in a vertical direction on a side wall of the word line and including a first side wall facing the word line, a second side wall opposite to the first side wall, and a third side wall and a fourth side wall spaced apart from each other in the second horizontal direction, a first capping liner located on the second side wall of the channel layer and including silicon nitride or a high-k dielectric material, a first buried insulating layer located on a side wall of the first capping liner, a second capping liner located on the third side wall of the channel layer and a side wall of the first buried insulating layer and including silicon nitride or a high-k dielectric material, and a second buried insulating layer located above the side wall of the first buried insulating layer, wherein the second capping liner is disposed between the first buried insulating layer and the second buried insulating layer.

### BRIEF DESCRIPTION OF THE DRAWINGS

Embodiments will be more clearly understood from the following detailed description taken in conjunction with the accompanying drawings in which:

FIG. 1 is a layout view illustrating a semiconductor device according to embodiments;

FIG. 2 is an enlarged layout view of a portion of a cell array region MCA of FIG. 1;

FIG. 3 is a cross-sectional view taken along line A1-A1′ of FIG. 2;

FIG. 4 is a cross-sectional view taken along line A2-A2′ of FIG. 2;

FIG. 5 is a horizontal cross-sectional view at a first vertical level LV1 of FIG. 3;

FIG. 6 is a horizontal cross-sectional view at a second vertical level LV2 of FIG. 3;

FIG. 7 is a horizontal cross-sectional view at a third vertical level LV3 of FIG. 3;

FIG. 8 is an enlarged view of region B of FIG. 3;

FIG. 9 is a cross-sectional view illustrating a semiconductor device according to embodiments;

FIG. 10 is a cross-sectional view illustrating a semiconductor device according to embodiments; and

FIGS. 11A, 11B, 12A, 12B, 13A, 13B, 14A, 14B, 15A, 15B, 15C, 16A, 16B, 16C, 17A, 17B, 17C, 18A, 18B, 18C, 19A, 19B, 19C, 20A, 20B, 20C, 21A, 21B, 21C, 22A, 22B, and 22C are schematic views illustrating a method of manufacturing a semiconductor device according to embodiments.

### DETAILED DESCRIPTION OF THE EMBODIMENTS

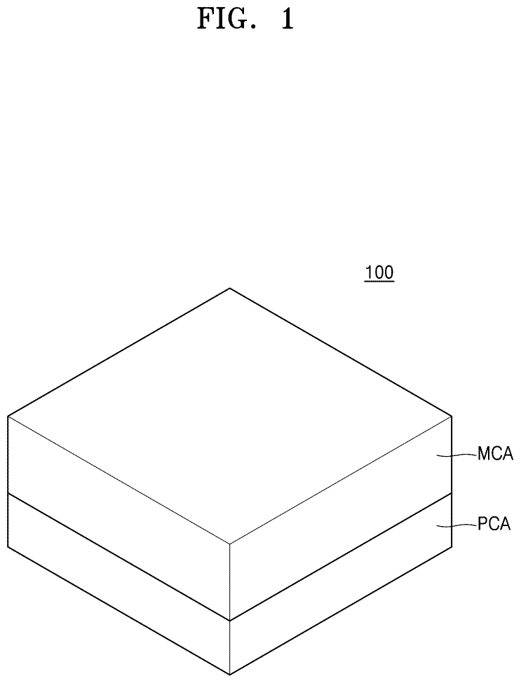

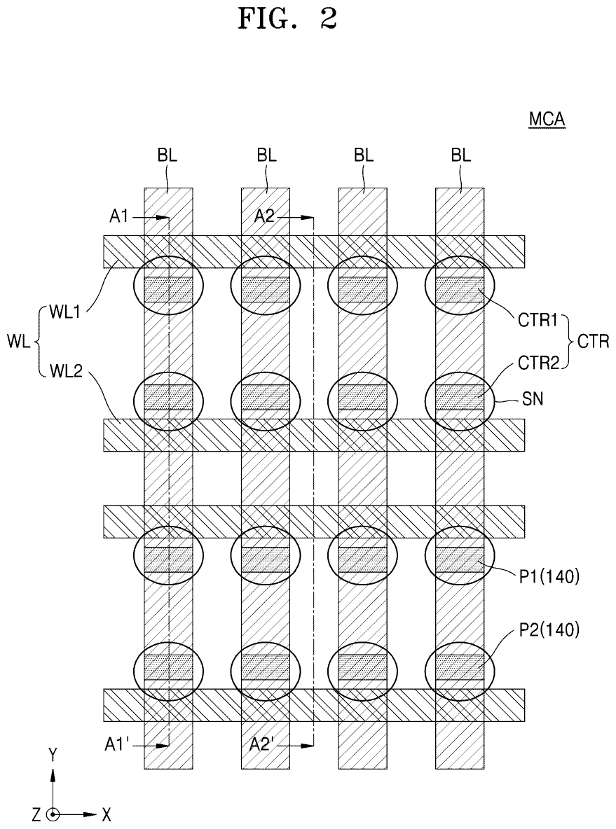

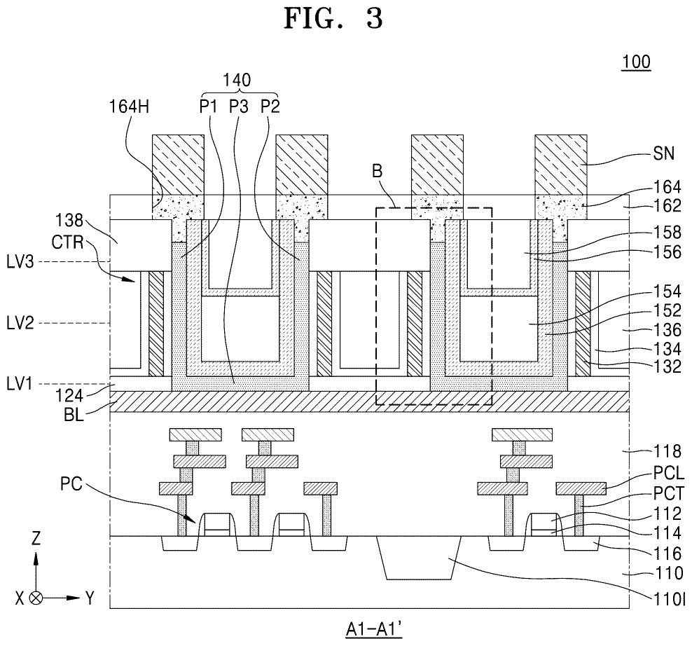

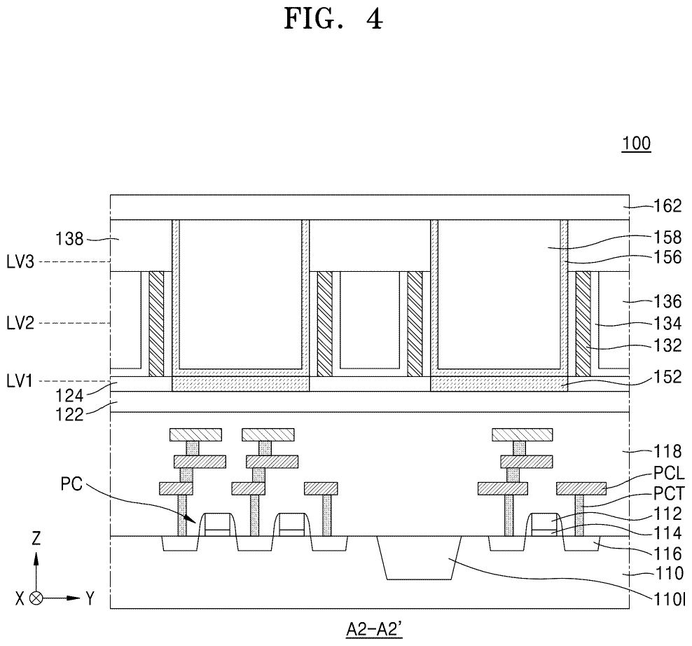

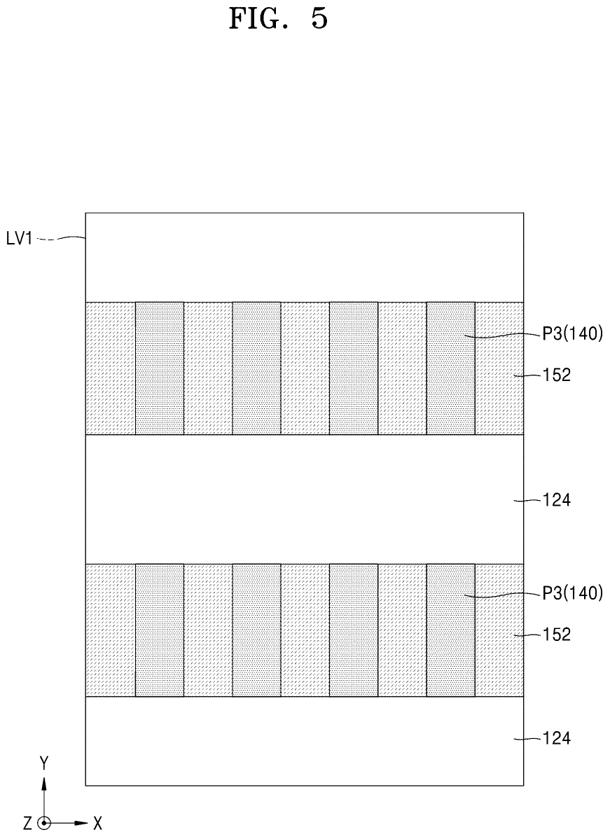

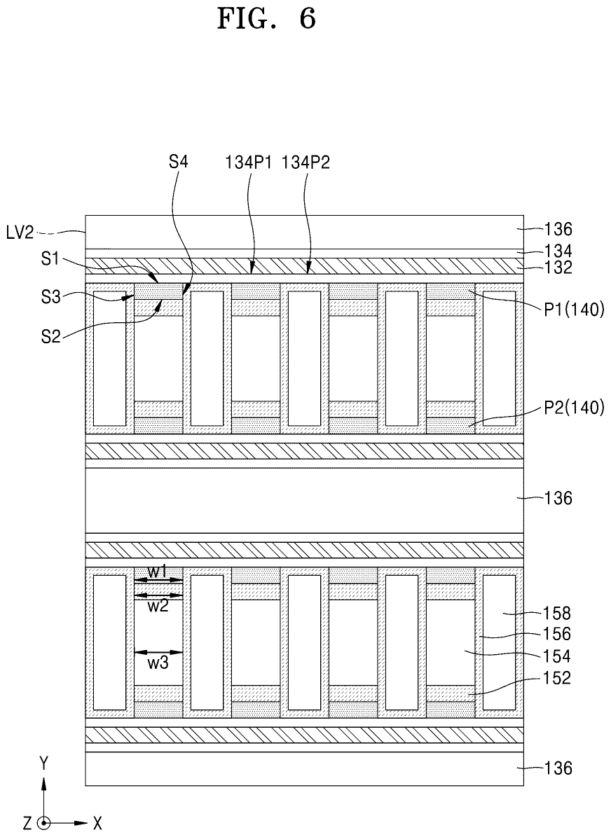

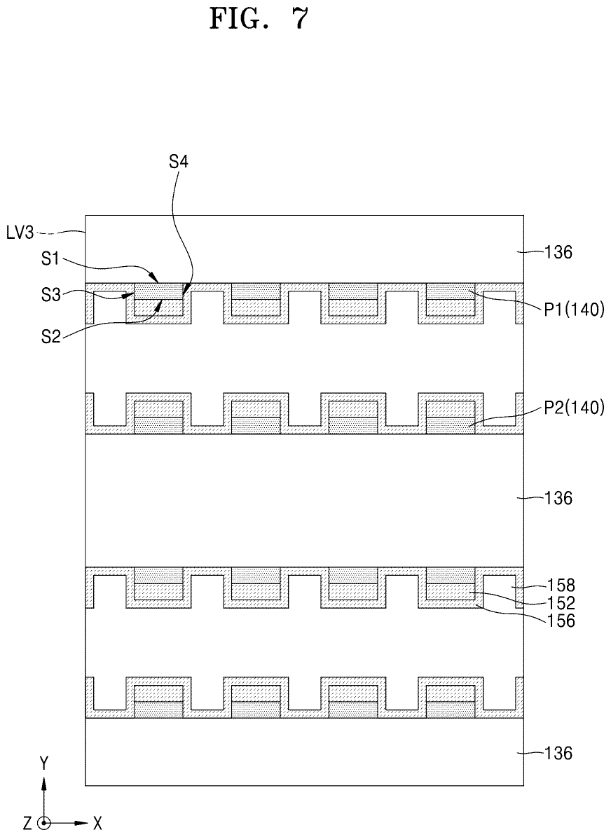

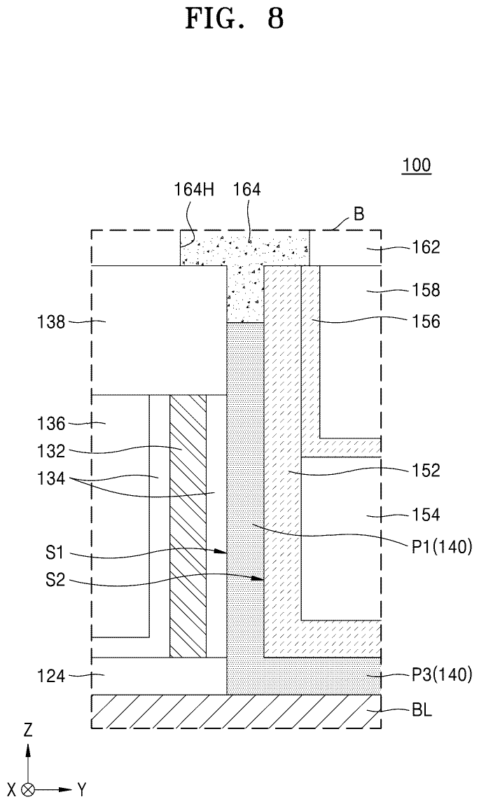

FIG. 1 is a layout view illustrating a semiconductor device 100 according to embodiments. FIG. 2 is an enlarged layout view of a portion of a cell array region MCA of FIG. 1. FIG. 3 is a cross-sectional view taken along line A1-A1′ of FIG. 2. FIG. 4 is a cross-sectional view taken along line A2-A2′ of FIG. 2. FIG. 5 is a horizontal cross-sectional view at a first vertical level LV1 of FIG. 3, FIG. 6 is a horizontal cross-sectional view at a second vertical level LV2 of FIG. 3, FIG. 7 is a horizontal cross-sectional view at a third vertical level LV3 of FIG. 3, and FIG. 8 is an enlarged view of region B of FIG. 3. The semiconductor device 100 may be, for example, a semiconductor chip (e.g., semiconductor memory chip), or semiconductor package including one or more semiconductor chips.

Referring to FIGS. 1 to 8, the semiconductor device 100 may include a peripheral circuit region PCA and a cell array region MCA located at a higher vertical level than the peripheral circuit region PCA.

In some embodiments, the cell array region MCA may include a memory cell region of a dynamic random access memory (DRAM) device, and the peripheral circuit region PCA may include a core region or a peripheral circuit region of the DRAM device. For example, the peripheral circuit region PCA may include peripheral circuit transistors PC for transmitting signals and/or power to a memory cell array included in the cell array region MCA. In some embodiments, the peripheral circuit transistors PC may constitute various circuits such as a command decoder, control logic, address buffer, row decoder, column decoder, sense amplifier, and data input/output circuit.

As illustrated in FIG. 2, in the cell array region MCA, a plurality of word lines WL extend in a first horizontal direction X and a plurality of bit lines BL extend in a second horizontal direction Y. An item, layer, or portion of an item or layer described as extending in a particular direction may be further described to extend “lengthwise” in the particular direction, which indicates, unless the context indicates otherwise, that the item, layer, or portion of the item or layer has a length in the particular direction and a width perpendicular to that direction, where the length is greater than the width. A plurality of cell transistors CTR may be located at intersections between the plurality of word lines WL and the plurality of bit lines BL. A plurality of storage nodes SN may be respectively located above the plurality of cell transistors CTR.

The plurality of word lines WL may include a first word line WL1 and a second word line WL2 that are alternately arranged in the second horizontal direction Y, and the plurality of cell transistors CTR may include a first cell transistor CTR1 and a second transistor CTR2 that are alternately arranged in the second horizontal direction Y. The first cell transistor CTR1 may be located adjacent to the first word line WL1, and the second transistor CTR2 may be located adjacent to the second word line WL2. The first word line WL1 may be one of a plurality of first word lines and the second word line WL2 may be one of a plurality of second word lines, so that the plurality of first word lines and plurality of second word lines are alternately arranged in the second horizontal direction Y. Similarly, the first cell transistor CTR1 may be one of a plurality of first cell transistors and the second cell transistor CTR2 may be one of a plurality of second cell transistors, so that the plurality of first transistors and plurality of second transistors are alternately arranged in the second horizontal direction Y.

The first cell transistor CTR1 and the second cell transistor CTR2 may have a mirror symmetric structure with respect to each other. For example, the first cell transistor CTR1 and the second cell transistor CTR2 may have a mirror symmetric structure with respect to a center line which is between the first cell transistor CTR1 and the second cell transistor CTR2 and extends in the first horizontal direction X.

In some embodiments, the plurality of word lines WL may have a width (e.g., in the second horizontal direction Y) of IF, the plurality of word lines WL may have a pitch (i.e. the sum of a width and an interval, in the second horizontal direction Y) of 2F, the plurality of bit lines BL may have a width (e.g., in the first horizontal direction X) of IF, the plurality of bit lines BL may have a pitch (i.e. the sum of a width and an interval, in the first horizontal direction X) of 2F, and a unit area for forming one cell transistor CTR may be 4F². Therefore, the cell transistor CTR may be of a crosspoint type requiring a relatively small unit area, which may be advantageous in improving the degree of integration of the semiconductor device 100. The cell transistor CTR may be a vertical cell transistor, for example, a DRAM vertical cell transistor.

A substrate 110 may include or be formed of silicon, for example, single crystalline silicon, polycrystalline silicon, or amorphous silicon. In some embodiments, the substrate 110 may include or be formed of at least one selected from among Ge, SiGe, SiC, GaAs, InAs, and InP. In some embodiments, the substrate 110 may include a conductive region, for example, a well doped with impurities or a structure doped with impurities.

A device isolation layer 110I defining an active region may be located on the substrate 110, and peripheral circuit transistors PC may be located on the substrate 110. Each of the peripheral circuit transistors PC may include a gate electrode 112, a gate insulating layer 114, and source/drain regions 116 and may be electrically connected to the bit line BL or the word line WL through, for example, peripheral circuit wires PCL and peripheral circuit contacts PCT.

On the substrate 110, a peripheral circuit insulating layer 118 may cover the peripheral circuit transistors PC, the peripheral circuit wires PCL, and the peripheral circuit contacts PCT. The peripheral circuit insulating layer 118 may include or be formed of an oxide film, a nitride film, a low-k dielectric film, or a combination thereof and may have a laminated structure of a plurality of insulating layers.

The bit line BL extending in the second horizontal direction Y may be located on the peripheral circuit insulating layer 118. In some embodiments, the bit line BL may include or be formed of Ti, TiN, Ta, TaN, Mo, Ru, W, WN, Co, Ni, TiSi, TiSiN, WSi, WSIN, TaSi, TaSiN, RuTiN, CoSi, NiSi, polysilicon, or a combination thereof.

A bit line separation insulating layer 122 may be located between the plurality of bit lines BL. The bit line separation insulating layer 122 may include or be formed of an oxide film, a nitride film, a low-k dielectric film, or a combination thereof.

In some embodiments, a shielding structure extending in the second horizontal direction Y may be further located between the plurality of bit lines BL. The shielding structure may include a conductive material, such as a metal. In some embodiments, the shielding structure may be formed of a conductive material and may include an air gap or a void therein, or, in other embodiments, air gaps may be defined in the bit line separation insulating layer 122 instead of the shielding structure.

An etch stop film 124 extending in the first horizontal direction X may be located on the plurality of bit lines BL and the bit line separation insulating layer 122. In some embodiments, the etch stop film 124 may include or may be silicon nitride.

A pair of gate electrodes 132 may be spaced apart from each other on the etch stop film 124. In some embodiments, the pair of gate electrodes 132 may be spaced apart from each other in the first horizontal direction X, and each of the pair of gate electrodes 132 may correspond to the plurality of word lines WL. In some embodiments, the pair of gate electrodes 132 may include or be formed of Ti, TiN, Ta, TaN, Mo, Ru, W, WN, Co, Ni, TiSi, TiSiN, WSi, WSIN, TaSi, TaSiN, RuTiN, CoSi, NiSi, polysilicon, or a combination thereof.

In some embodiments, the pair of gate electrodes 132 may have a bar shape or line pattern shape extending in the first horizontal direction X. For example, the pair of gate electrodes 132 may be formed by forming a mask pattern in a line pattern shape on a gate electrode layer and patterning the gate electrode layer using the mask pattern as an etching mask, and thus the pair of gate electrodes 132 may have a flat shape of a bar type or line type.

In some embodiments, as illustrated in FIG. 3, the pair of gate electrodes 132 may have vertical or substantially vertical side walls and may have a width that is constant in the second horizontal direction Y over the total height thereof. In other embodiments, the pair of gate electrodes 132 may have inclined side walls, and the width of an upper portion of the pair of gate electrodes 132 in the second horizontal direction Y may be smaller than the width of a lower portion of the pair of gate electrodes 132 in the second horizontal direction Y. Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

The pair of gate electrodes 132 may each have side walls on which a gate insulating layer 134 is located. The gate insulating layer 134 may be located on both side walls of the pair of gate electrodes 132 and, for example, may extend from side walls, which face each other, of the pair of gate electrodes 132 onto the upper surface of the etch stop film 124 located between the pair of gate electrodes 132.

In some embodiments, the gate insulating layer 134 may include or be formed of at least one selected from among high-k dielectric materials and ferroelectric materials that have a higher dielectric constant than silicon oxide. In some embodiments, the gate insulating layer 134 may include or be formed of at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAIO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PbZrTiO), strontium bismuth tantalate (StTaBiO), bismuth iron oxide (BiFcO), strontium titanium oxide (SrTiO), yttrium oxide (YO), aluminum oxide (AlO), and lead scandium tantalum oxide (PbScTaO).

In a space between the pair of gate electrodes 132, a mold insulating layer 136 may be located on the gate insulating layer 134. The mold insulating layer 136 may have an upper surface that is at the same level of upper surfaces of the pair of gate electrodes 132 and may fill the space between the pair of gate electrodes 132 while extending in the first horizontal direction X. A mold cover layer 138 may be located on the upper surfaces of the pair of gate electrodes 132 and the mold insulating layer 136. In some embodiments, the mold insulating layer 136 may include or be formed of silicon oxide or a low-k dielectric material, and the mold cover layer 138 may include or be formed of silicon nitride.

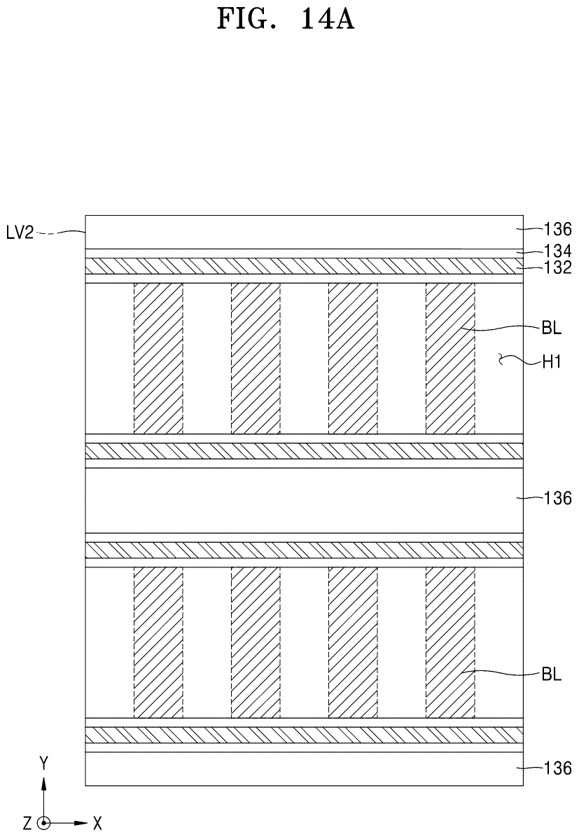

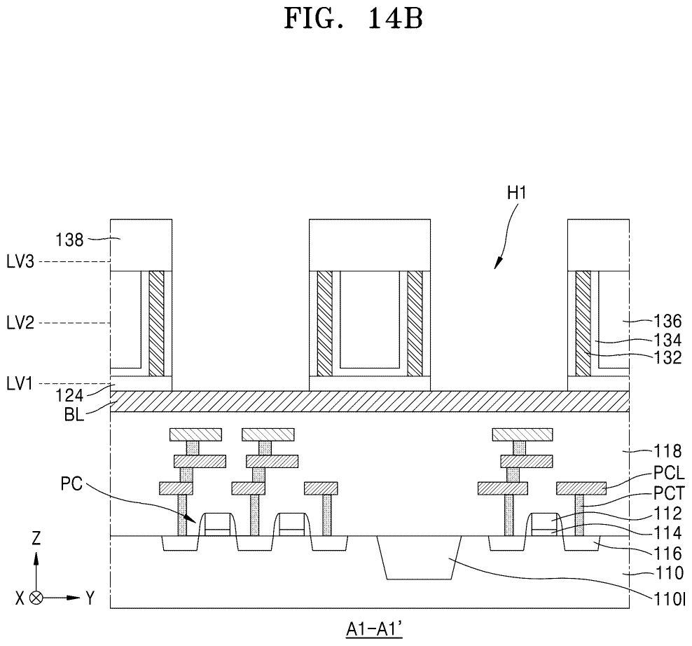

The pair of gate electrodes 132, the gate insulating layer 134 on the side wall of the pair of gate electrodes 132, the mold insulating layer 136 filling the space between the pair of gate electrodes 132, and the mold cover layer 138 may be referred to as a mold line pattern. The mold line pattern may extend in the first horizontal direction X, and a mold opening H1 (see FIG. 14B) may be defined between one mold line pattern and another mold line pattern adjacent thereto. The mold opening H1 may have a bottom portion exposing upper surfaces of the bit line BL and the bit line separation insulating layer 122.

A channel layer 140 may be located in the mold opening H1. The channel layer 140 may have a U-shaped vertical cross-section and may include a first vertical portion P1, a second vertical portion P2, and a connection portion P3. The first vertical portion P1 may be located on a first side wall of the mold opening H1 and may extend in a vertical direction Z, and the second vertical portion P2 may be located on a second side wall of the mold opening H1 and may extend in the vertical direction Z. The second vertical portion P2 may be spaced apart from the first vertical portion P1 in the second horizontal direction Y. The connection portion P3 may be connected to bottom portions of the first vertical portion P1 and the second vertical portion P2 and may be located on the upper surface of the bit line BL.

With respect to one channel layer 140 located between two mold line patterns, the first vertical portion P1 may be located to face the gate electrode 132 within one mold line pattern, and the second vertical portion P2 may be located to face the gate electrode 132 within the other mold line pattern. The gate electrode 132 which is within one mold line pattern and faces the first vertical portion P1 may correspond to the first word line WL1 (see FIG. 1), and the first vertical portion P1, the first word line WL1, and the gate insulating layer 134 therebetween may form the first cell transistor CTR1 (see FIG. 1). The gate electrode 132 which is within one mold line pattern and faces the second vertical portion P2 may correspond to the second word line WL2 (see FIG. 1), and the second vertical portion P2, the second word line WL2, and the gate insulating layer 134 therebetween may form the second cell transistor CTR2 (see FIG. 1). Accordingly, the first cell transistor CTR1 and the second cell transistor CTR2 may have a mirror symmetric structure with respect to each other.

In some embodiments, the channel layer 140 may include or be formed of at least one of zinc tin oxide (ZnₓSn_{y}O), indium zinc oxide (InₓZn_{y}O), zinc oxide (ZnOₓ), indium gallium zinc oxide (InₓGa_{y}Zn_{z}O), indium gallium silicon oxide (InₓGa_{y}Si_{z}O), indium tungsten oxide (InₓW_{y}O), indium oxide (InₓO), tin oxide (SnₓO), titanium oxide (TiₓO), zinc oxynitride (ZnₓON_{z}), magnesium zinc oxide (MgₓZn_{y}O), zirconium indium zinc oxide (ZrₓIn_{y}Zn₂O), hafnium indium zinc oxide (HfₓIn_{y}Zn_{z}O), tin indium zinc oxide (SnₓIn_{y}Zn_{z}O), aluminum tin indium zinc oxide (AlₓSn_{y}In_{z}ZnₐO), silicon indium zinc oxide (SiₓIn_{y}Zn_{z}O), aluminum zinc tin oxide (AlₓZn_{y}Sn₂O), gallium zinc tin oxide (GaₓZn_{y}Sn_{z}O), and zirconium zinc tin oxide (ZrₓZn_{y}Sn₂O).

In some embodiments, an upper portion of the first vertical portion P1 and an upper portion of the second vertical portion P2 of the channel layer 140 may be further doped with impurity ions and the connection portion P3 of the channel layer 140 may be further doped with impurity ions. The connection portion P3 of the channel layer 140 may function as a source contact and the upper portion of the first vertical portion P1 and the upper portion of the second vertical portion P2 of the channel layer 140 may function as drain contacts.

In one mold opening H1, a plurality of channel layers 140 may be spaced apart from each other in the first horizontal direction X. The plurality of channel layers 140 may be located to vertically overlap each of the plurality of bit lines BL, and each connection portion P3 of the plurality of channel layers 140 may be located on each upper surface of the plurality of bit lines BL.

As illustrated in FIG. 6, in one example embodiment, the first vertical portion P1 and the second vertical portion P2 of the channel layer 140 may have a rectangular-shaped horizontal cross-section. The first vertical portion P1 of the channel layer 140 may include a first side wall S1 facing the gate electrode 132 (e.g., the word line WL) and a second side wall S2 opposite to and spaced apart from the first side wall S1 in the second horizontal direction Y. Furthermore, the first vertical portion P1 of the channel layer 140 may include a third side wall S3 and a fourth side wall S4 spaced apart from each other in the first horizontal direction X. The first side wall S1 of the first vertical portion P1 may be in contact with the gate insulating layer 134. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

A first capping liner 152 may be located on the second side wall S2 of the first vertical portion P1, a second side wall S2 of the second vertical portion P2, and an upper surface of the connection portion P3 of the channel layer 140. The first capping liner 152 may extend from the upper surface of the connection portion P3 onto the upper surface of the bit line separation insulating layer 122. The first capping liner 152 may be located on the entire second side wall S2 of the first vertical portion P1 and the entire second side wall S2 of the second vertical portion P2. The first capping liner 152 may include or be formed of silicon nitride or a high-k dielectric material. In some embodiments, the high-k dielectric material may be at least one material selected from among hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), lead zirconate titanate (PbZrTiO), strontium bismuth tantalate (StTaBiO), bismuth iron oxide (BiFcO), strontium titanium oxide (SrTiO), yttrium oxide (YO), aluminum oxide (AlO), and lead scandium tantalum oxide (PbScTaO).

A first buried insulating layer 154 may be located on the first capping liner 152 and may fill a space between the second side wall S2 of the first vertical portion P1 and the second side wall S2 of the second vertical portion P2. For example, the first buried insulating layer 154 may be located on a side wall of a portion of the first capping liner 152 located on the second side wall S2 of the first vertical portion P1 and on the upper surface of a portion of the first capping liner 152 located on the upper surface of the connection portion P3. The upper surface of the first buried insulating layer 154 may be at a lower level than the upper surface of the channel layer 140 (e.g., an upper surface of the first vertical portion P1).

The first buried insulating layer 154 may be spaced apart from the second side wall S2 of the first vertical portion P1 of the channel layer 140 in the first horizontal direction X and may not be in contact with the second side wall S2 of the first vertical portion P1 of the channel layer 140 due to the first capping liner 152 that is disposed between the first buried insulating layer 154 and the second side wall S2.

In some embodiments, the first vertical portion P1 of the channel layer 140 may have a first width w1 in the first horizontal direction X, the first buried insulating layer 154 may have a second width w2 equal to the first width w1 in the first horizontal direction X, and the first capping liner 152 may have a third width w3 equal to the first width w1 in the first horizontal direction X.

In one mold opening H1, a plurality of first buried insulating layers 154 may be spaced apart from each other in the first horizontal direction X. The plurality of first buried insulating layers 154 may be at positions corresponding to each of the plurality of channel layers 140 and may be located to vertically overlap each of the plurality of bit lines BL.

A second capping liner 156 may be located on the third side wall S3 and the fourth side wall S4 of the first vertical portion P1 and on a side wall of the gate insulating layer 134 and a side wall of the first buried insulating layer 154. In some embodiments, the second capping liner 156 may include silicon nitride or a high-k dielectric material.

In some embodiments, the gate insulating layer 134 may include a first portion 134P1 and a second portion 134P2. The first portion 134P1 of the gate insulating layer 134 may be located between the gate electrode 132 and the channel layer 140 and may be in contact with the channel layer 140. The second portion 134P2 of the gate insulating layer 134 may be located between the gate electrode 132 and the second capping liner 156 and may be in contact with the second capping liner 156.

A second buried insulating layer 158 may be located above the side wall of the first buried insulating layer 154. For example, in one mold opening H1, the second buried insulating layer 158 may fill a space between the plurality of first buried insulating layers 154, and the second capping liner 156 may be disposed between the first buried insulating layer 154 and the second buried insulating layer 158. For example, as illustrated in FIG. 7, at a third vertical level LV3 which is higher than the upper surface of the gate electrode 132, an upper portion of the second buried insulating layer 158 may have a horizontal cross-sectional shape filling the mold opening H1 and extending in the first horizontal direction X. As illustrated in FIG. 6, at the second vertical level LV2 which is lower than the upper surface of the gate electrode 132 and higher than a bottom surface of the gate electrode 132, a lower portion of the second buried insulating layer 158 may fill the space between the plurality of first buried insulating layers 154.

In some embodiments, the first buried insulating layer 154 and the second buried insulating layer 158 may include or be formed of silicon oxide or a low-k dielectric material.

The second side wall S2 of the channel layer 140 may be covered by the first capping liner 152, and the third side wall S3 and the fourth side wall S4 of the channel layer 140 may be covered by the second capping liner 156. Accordingly, the channel layer 140 may not contact the first buried insulating layer 154 or the second buried insulating layer 158. Therefore, an oxygen path to the channel layer 140 may be blocked when using the semiconductor device 100, and reliability of the cell transistor CTR may be improved.

An upper insulating layer 162 may be located on the second buried insulating layer 158 and the mold cover layer 138. A landing pad 164 may be located in a landing pad opening 164H passing through the upper insulating layer 162. The landing pad 164 may be in contact with the upper surface of the channel layer 140 (e.g., the upper surface of the first vertical portion P1 and an upper surface of the second vertical portion P2). In some embodiments, the landing pad 164 may include or be formed of Ti, TiN, Ta, TaN, W, WN, TiSIN, WSIN, polysilicon, or a combination thereof.

The storage node SN may be located on the landing pad 164. In some embodiments, the storage node SN may include or be a capacitor having a metal-insulator-metal (MIM) structure. In other embodiments, the storage node SN may include or be a variable resistance memory component, phase change memory component, magnetic memory component, and the like, resulting, for example, in capacitor-less memory such as capacitor-less DRAM.

According to the embodiments described above, the second side wall S2 of the channel layer 140 may be covered by the first capping liner 152, and the third side wall S3 and the fourth side wall S4 of the channel layer 140 may be covered by the second capping liner 156. Accordingly, the channel layer 140 may not contact the first buried insulating layer 154 or the second buried insulating layer 158. Therefore, an oxygen path to the channel layer 140 may be blocked when using the semiconductor device 100, and the reliability of the cell transistor CTR may be improved. Oxygen supply to the connection portion P3 of the channel layer 140, which is in contact with the bit line BL, may be blocked during annealing, thus improving performance of the cell transistor CTR, for example, increasing on-current.

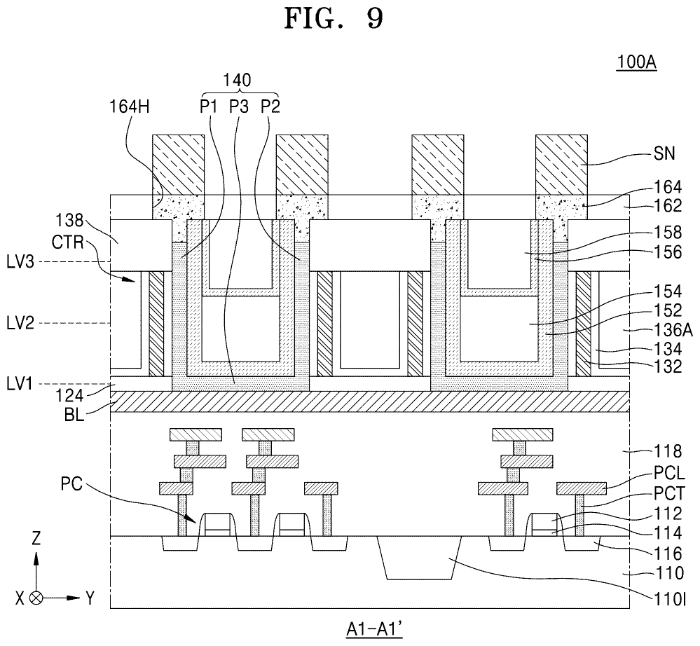

FIG. 9 is a cross-sectional view illustrating a semiconductor device 100A according to embodiments.

Referring to FIG. 9, a mold insulating layer 136A located between a pair of gate electrodes 132 may include an air space. For example, the mold insulating layer 136A may include a space defined by portions of a gate insulating layer 134 which are located on side walls of the pair of gate electrodes 132 and a portion of the gate insulating layer 134 which is located on an upper surface of an etch stop film 124, and air instead of any material layer may fill the space. In other embodiments, the mold insulating layer 136A may include an insulating material layer that includes a void or seam therein. For example, an insulating material layer may be formed on the side walls and the upper surface of the gate insulating layer 134 and a void or seam may be located within the insulating material layer. The term “air” as discussed herein, may refer to atmospheric air, or other gases that may be present during the manufacturing process. A void or seam may refer to a gap forming a vacuum therein, or may also include air.

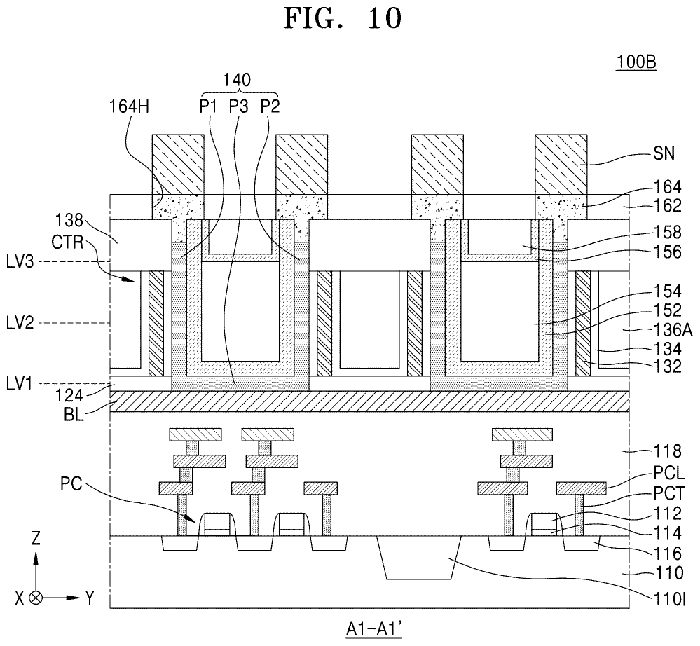

FIG. 10 is a cross-sectional view illustrating a semiconductor device 100B according to embodiments.

Referring to FIG. 10, the upper surface (e.g., an upper-most surface, or top surface) of a first buried insulating layer 154 may be at a higher level than the upper surface (e.g., an upper-most surface, or top surface) of a gate electrode 132 and at a lower level than the upper surface (e.g., an upper-most surface, or top surface) of a channel layer 140 (e.g., the upper surface of a first vertical portion P1 or the upper surface of a second vertical portion P2). The bottom surface (e.g., lower-most surface) of a second buried insulating layer 158 may also be at a higher level than the upper surface of the gate electrode 132 and at a lower level than the upper surface of a channel layer 140 (e.g., the upper surface of the first vertical portion P1 or the upper surface of the second vertical portion P2). The higher level may refer to a vertical level, in the Z direction, above a top surface of the substrate 110, for example.

In some embodiments, a portion, which is at a higher vertical level than the upper surface of the first buried insulating layer 154, of the channel layer 140 (e.g., a portion of the first vertical portion P1 or a portion of the second vertical portion P2, which is at a higher vertical level than the upper surface of the first buried insulating layer 154) may be doped with impurity ions, and the portion of the channel layer 140 may function as a drain contact that is electrically connected to a landing pad 164.

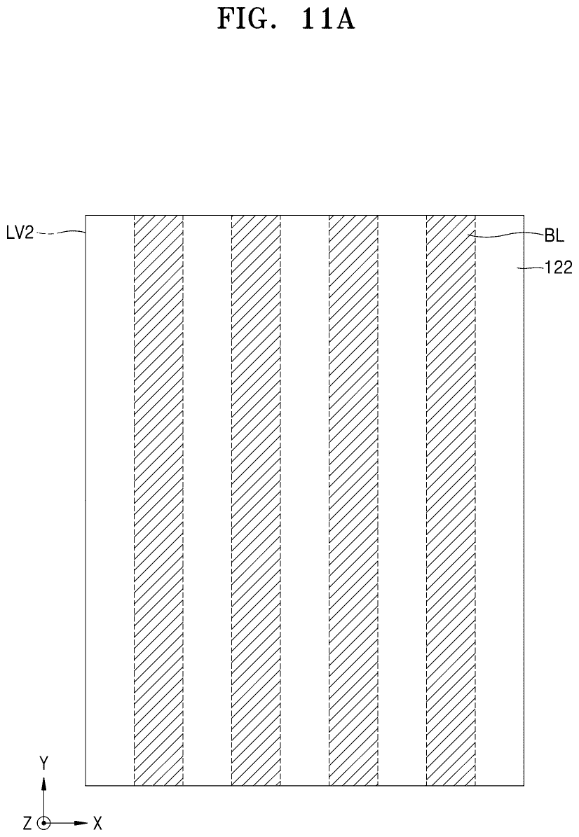

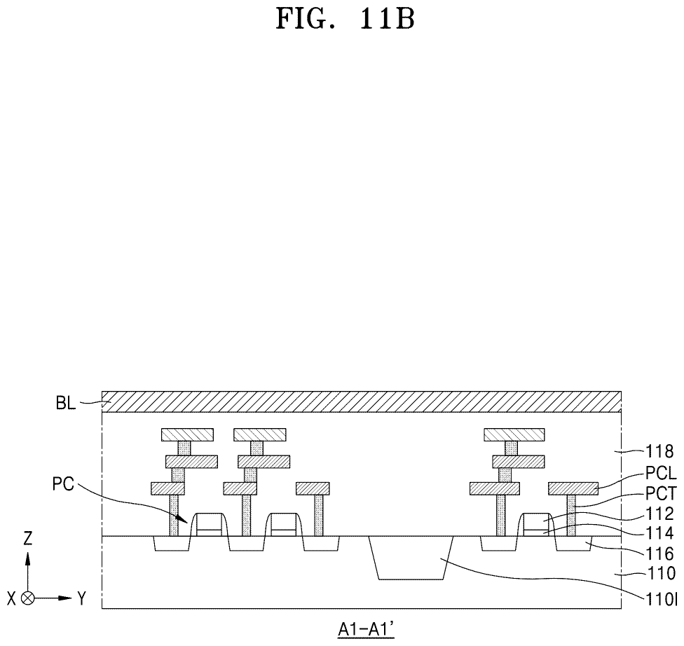

FIGS. 11A, 11B, 12A, 12B, 13A, 13B, 14A, 14B, 15A, 15B, 15C, 16A, 16B, 16C, 17A, 17B, 17C, 18A, 18B, 18C, 19A, 19B, 19C, 20A, 20B, 20C, 21A, 21B, 21C, 22A, 22B, and 22C are schematic views illustrating a method of manufacturing a semiconductor device 100, according to embodiments.

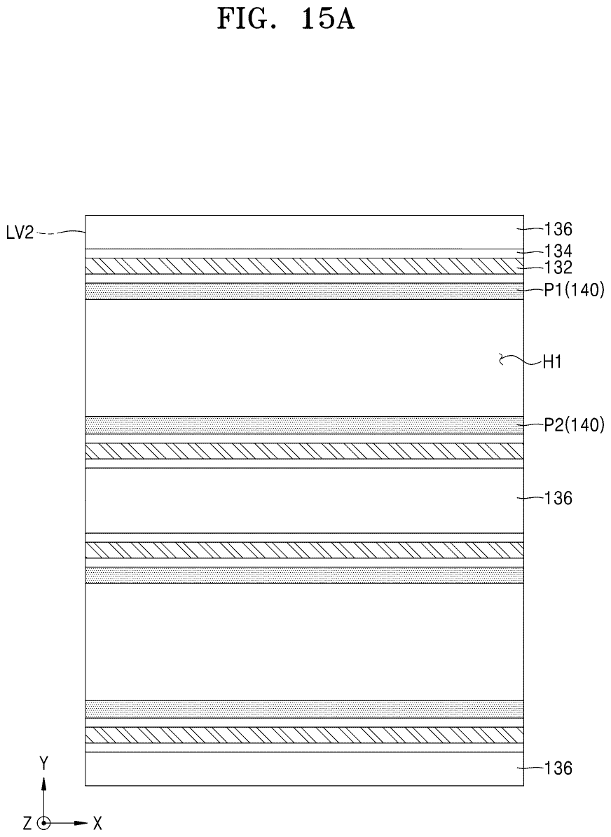

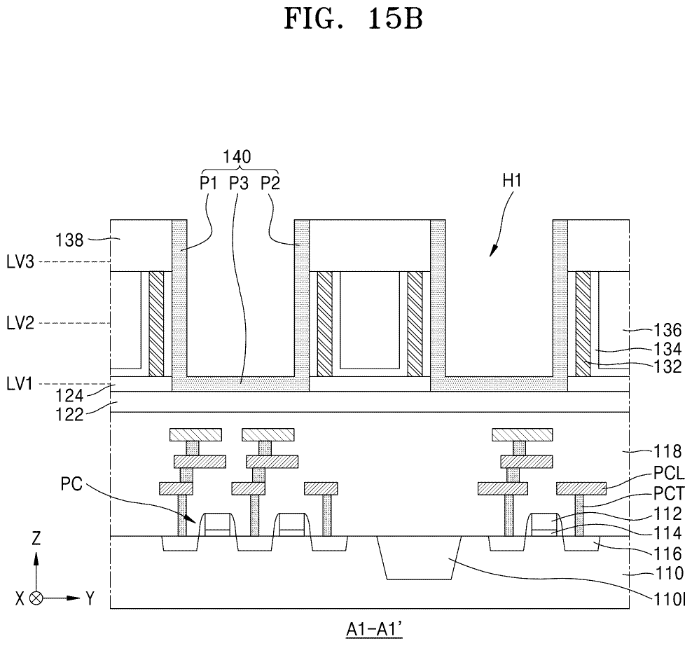

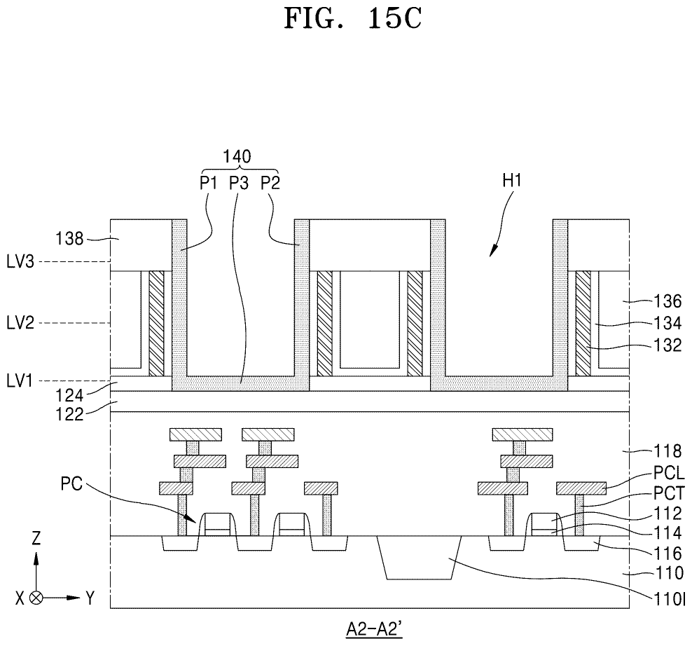

Specifically, FIGS. 11A, 12A, 13A, 14A, 15A, 16A, 17A, 18A, 19A, 20A, 21A, and 22A are horizontal cross-sectional views at a second vertical level LV2 of FIG. 3, according to a process sequence, FIGS. 11B, 12B, 13B, 14B, 15B, 16B, 17B, 18B, 19B, 20B, 21B, and 22B are cross-sectional views taken along line A1-A1′ of FIG. 2, and FIGS. 15C, 16C, 17C, 18C, 19C, 20C, 21C, and 22C are cross-sectional views taken along line A2-A2′ of FIG. 2.

Referring to FIGS. 11A and 11B, peripheral circuit transistors PC, peripheral circuit wires PCL, peripheral circuit contacts PCT, and a peripheral circuit insulating layer 118 may be formed on a substrate 110. Each of the peripheral circuit transistors PC may include a gate electrode 112, a gate insulating layer 114, and source/drain regions 116. On the substrate 110, the peripheral circuit insulating layer 118 may cover the peripheral circuit transistors PC, the peripheral circuit wires PCL, and the peripheral circuit contacts PCT.

Thereafter, on the peripheral circuit insulating layer 118, a plurality of bit lines BL extending in a second horizontal direction Y and a bit line separation insulating layer 122 filling a space between the plurality of bit lines BL are formed.

In some embodiments, the bit line separation insulating layer 122 is formed on the peripheral circuit insulating layer 118, a bit line formation space (not shown) may be formed by patterning the bit line separation insulating layer 122 with a mask pattern (not shown), a conductive layer may be formed in the bit line formation space, and an upper portion of the conductive layer may be removed so that the upper surface of the bit line separation insulating layer 122 may be exposed, thereby forming the plurality of bit lines BL.

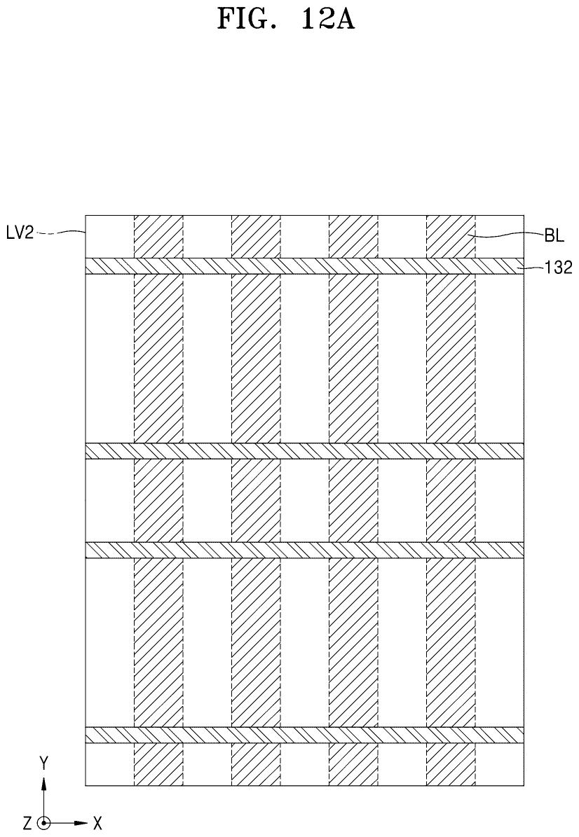

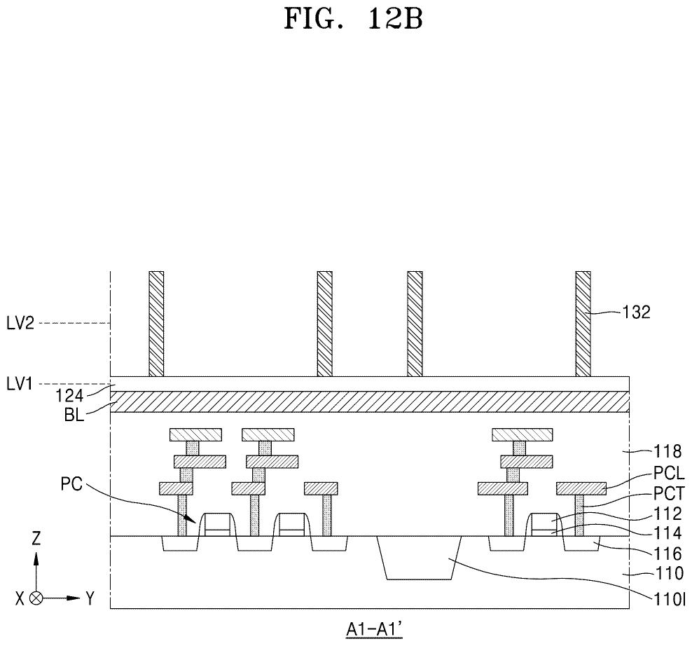

Referring to FIGS. 12A and 12B, an etch stop film 124 is formed on the plurality of bit lines BL and the bit line separation insulating layer 122. After that, gate electrodes 132 extending in a first horizontal direction X are formed on the etch stop film 124.

In some embodiments, the etch stop film 124 is formed on the plurality of bit lines BL and the bit line separation insulating layer 122, a gate electrode layer is formed on the etch stop film 124 with conductive materials, a mask pattern is formed on the gate electrode layer, and then the gate electrode layer is patterned, thereby forming the gate electrodes 132.

In some embodiments, the gate electrodes 132 may be located with predetermined intervals in the second horizontal direction Y. For example, as illustrated in FIG. 12A, odd-numbered gate electrodes 132 may be located with equal intervals (or at the same pitch) and even-numbered gate electrodes 132 may be located with equal intervals (or at the same pitch). A space between two adjacent gate electrodes 132 may differ from a space between two other adjacent gate electrodes 132.

In other embodiments, unlike the illustration in FIG. 12A, a space between two adjacent gate electrodes 132 may be the same as a space between any two other adjacent gate electrodes 132.

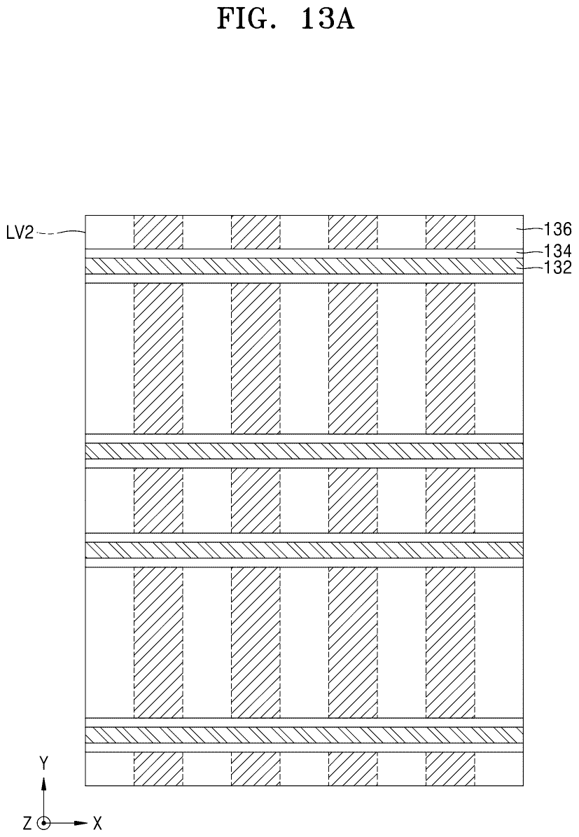

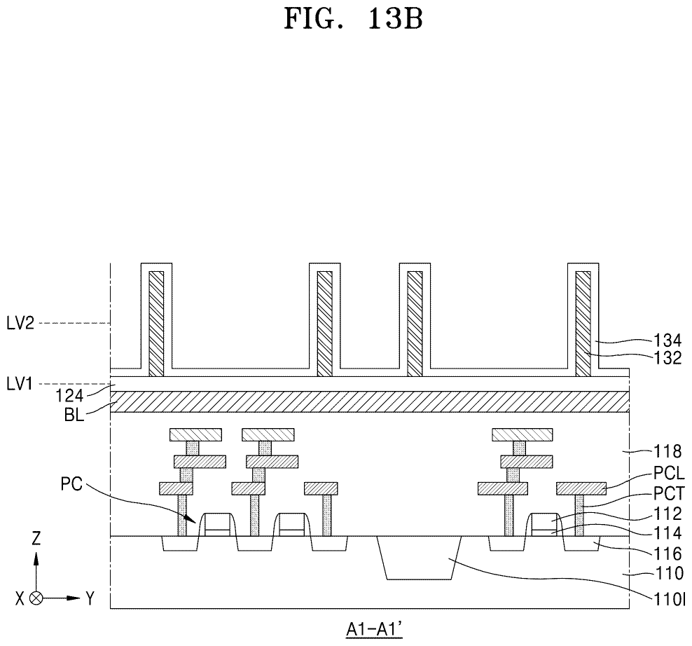

Referring to FIGS. 13A and 13B, a gate insulating layer 134 covering the gate electrodes 132 is formed on the etch stop film 124. The gate insulating layer 134 may conformally cover upper surfaces and both side walls of the gate electrodes 132.

In some embodiments, the gate insulating layer 134 may be formed using at least one of a chemical vapor deposition (CVD) process, a low pressure CVD process, a plasma-enhanced CVD process, a MOCVD process, and an atomic layer deposition process.

Referring to FIGS. 14A and 14B, a mold insulating layer 136 is formed on the gate insulating layer 134, and an upper portion of the mold insulating layer 136 may be planarized so that the upper surfaces of the gate electrodes 132 are exposed. Thereafter, a mold cover layer 138 covering a pair of the gate electrodes 132 and the mold insulating layer 136 therebetween may be formed, and a portion of the mold insulating layer 136, a portion of the gate insulating layer 134, and a portion of the etch stop film 124 that are not covered by the mold cover layer 138 may be removed so that the upper surface of the bit line BL and the upper surface of the bit line separation insulating layer 122 are exposed.

For example, the mold cover layer 138 may extend in the first horizontal direction X and may have a line pattern shape covering a pair of the gate electrodes 132. The pair of the gate electrodes 132, the gate insulating layer 134 on both of the side walls of the pair of the gate electrodes 132, the mold insulating layer 136 between the pair of the gate electrodes 132, and the mold cover layer 138 may be referred to as a mold line pattern. A mold opening H1 may be defined between one mold line pattern and another mold line pattern adjacent thereto. The mold opening H1 may have a bottom portion exposing upper surfaces of the bit line BL and the bit line separation insulating layer 122.

Referring to FIGS. 15A to 15C, a channel layer 140 is formed on an inner wall of the mold opening H1.

In some embodiments, the channel layer 140 includes or is formed of at least one of indium gallium zinc oxide (InₓGa_{y}Zn₂O), indium tungsten oxide (InₓW_{y}O), indium tin gallium oxide (InₓSn_{y}Ga_{z}O), indium aluminum zinc oxide (InₓAl_{y}Zn₂O), indium gallium oxide (InₓGa_{y}O), indium tin zinc oxide (InₓSn_{y}Zn₂O), indium gallium silicon oxide (InₓGa_{y}Si₂O), indium zinc oxide (InₓZn_{y}O), indium oxide (InₓO), magnesium aluminum zinc oxide (MgₓAl_{y}Zn₂O), zinc tin oxide (ZnₓSn_{y}O), zirconium zinc tin oxide (ZrₓZn_{y}Sn₂O), gallium zinc tin oxide (GaₓZn_{y}Sn₂O), aluminum zinc tin oxide (AlₓZn_{y}Sn₂O), and tin oxide (SnₓO).

In some embodiments, the channel layer 140 may be formed using at least one of a CVD process, a low pressure CVD process, a plasma-enhanced CVD process, a MOCVD process, and an atomic layer deposition process.

In some embodiments, the channel layer 140 may have a U-shaped vertical cross-section and may include a first vertical portion P1, a second vertical portion P2, and a connection portion P3. The first vertical portion P1 may be located on a first side wall of the mold opening H1 and may extend in a vertical direction Z, and the second vertical portion P2 may be located on a second side wall of the mold opening H1 and may extend in the vertical direction Z. The second vertical portion P2 may be spaced apart from the first vertical portion P1 in the second horizontal direction Y. The connection portion P3 may be connected to bottom portions of the first vertical portion P1 and the second vertical portion P2 and may be located on the upper surfaces of the bit line BL and the bit line separation insulating layer 122. The channel layer 140 may be formed on the inner wall of the mold opening H1 with a relatively small thickness and, therefore, the inside of the mold opening H1 may remain without being completely filled.

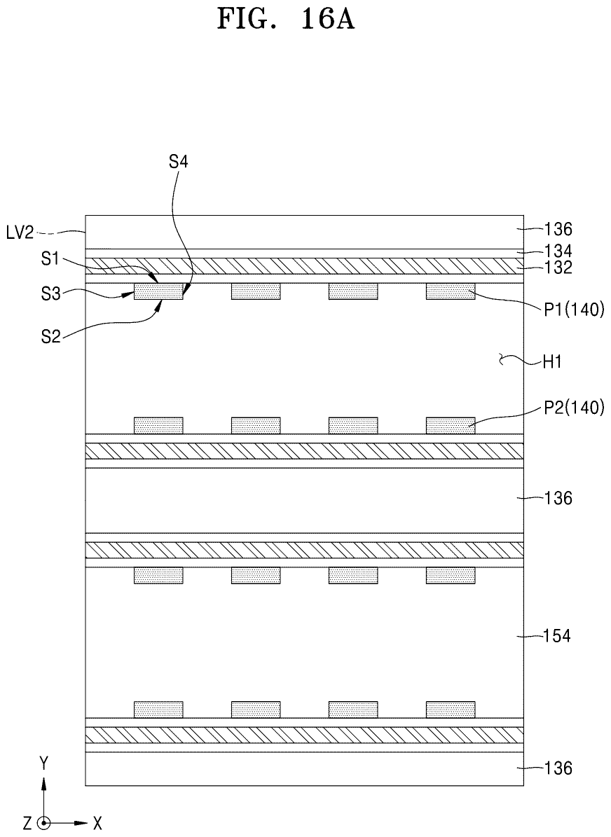

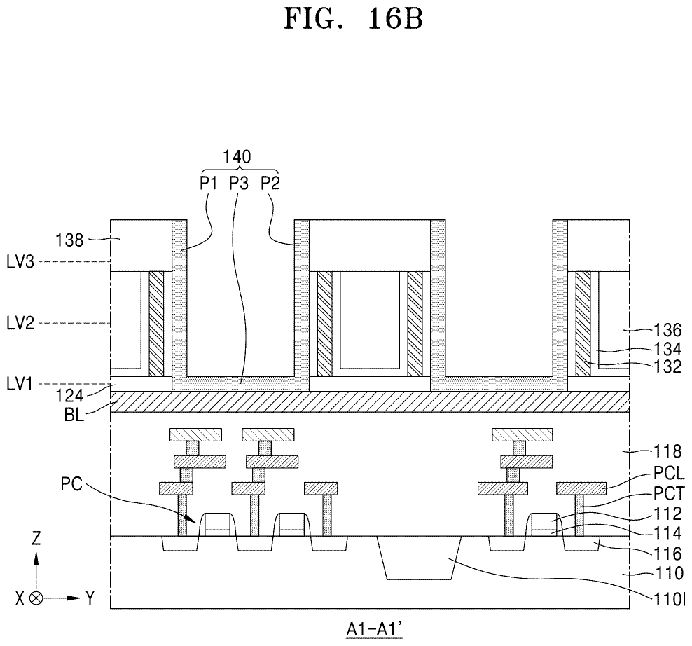

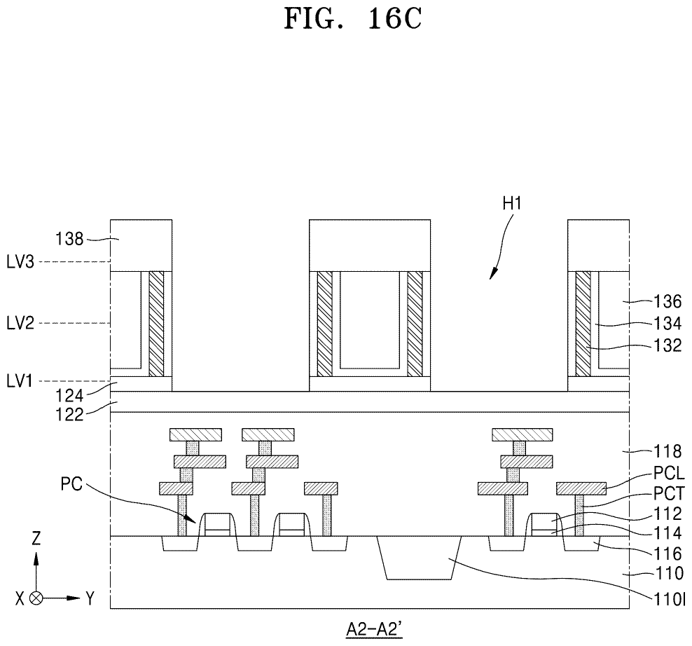

Referring to FIGS. 16A to 16C, a protective layer (not shown) filling the mold opening H1 may be formed on the channel layer 140 and a portion of the protective layer (not shown) may be removed by an etch back process. A portion of the channel layer 140 may also be removed in the etch back process for the protective layer, and a plurality of channel layers 140 may remain in the mold opening H1. Each of the plurality of channel layers 140 may be at a position vertically overlapping each of a plurality of bit lines BL.

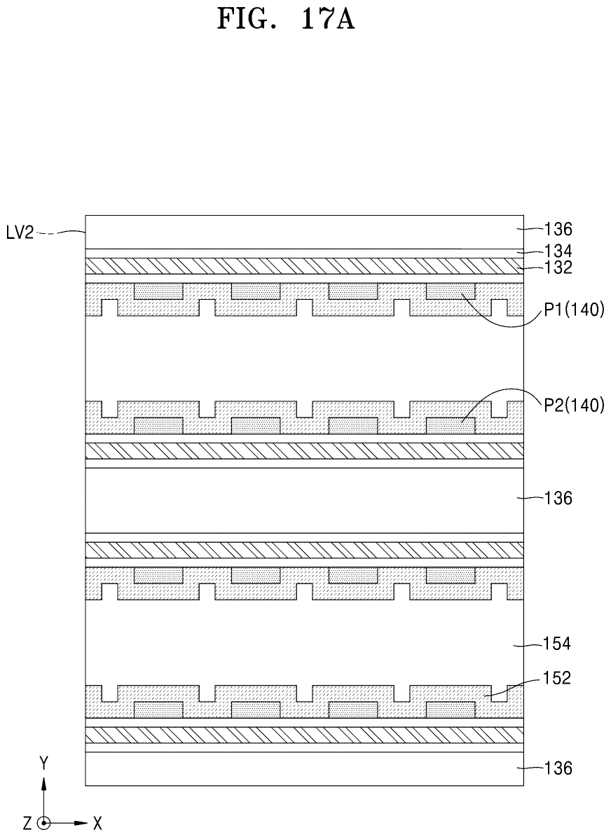

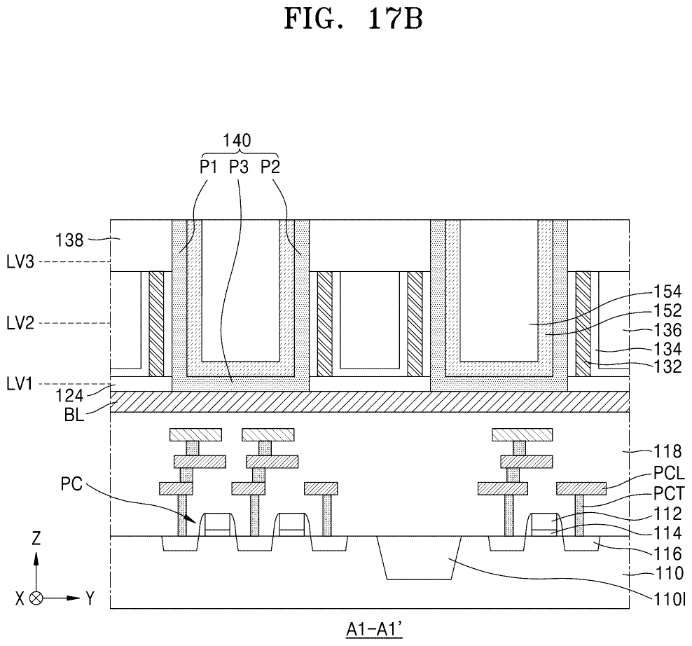

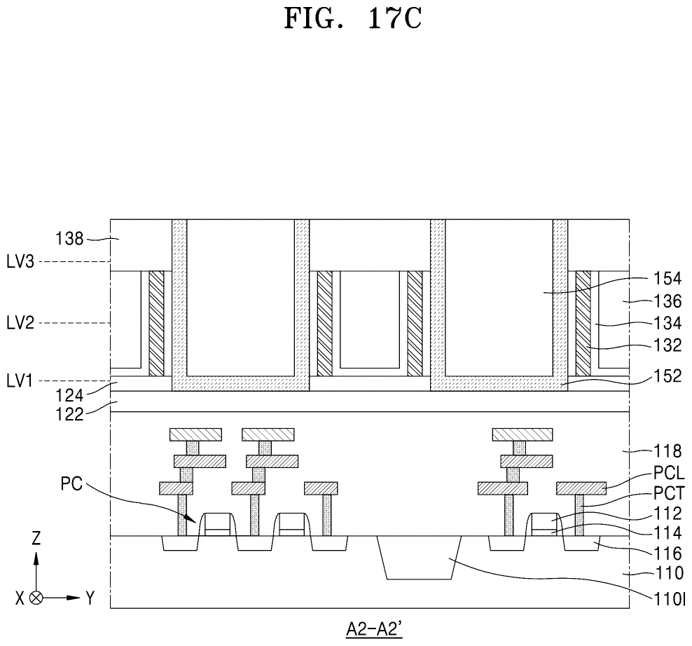

Referring to FIGS. 17A to 17C, a first capping liner 152 and a first buried insulating layer 154 are sequentially formed on the inner wall of the mold opening H1.

In some embodiments, the first capping liner 152 may be formed with silicon nitride or a high-k dielectric material, and the first buried insulating layer 154 may be formed with silicon oxide or a low-k dielectric material.

The first capping liner 152 may cover a surface of the channel layer 140 located on the inner wall of the mold opening H1 and may be located on a second side wall S2 (see FIG. 6) of the first vertical portion P1, the upper surface of the connection portion P3, and a second side wall S2 of the second vertical portion P2 of the channel layer 140.

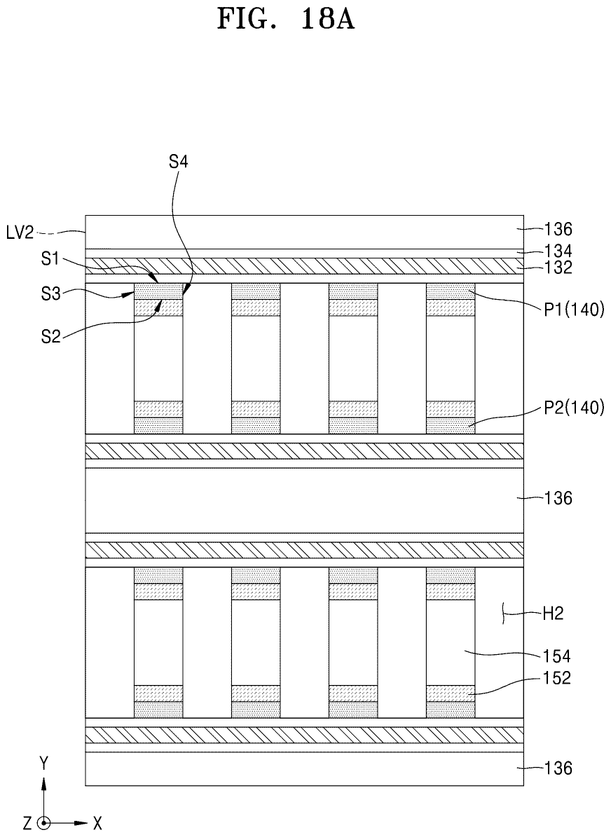

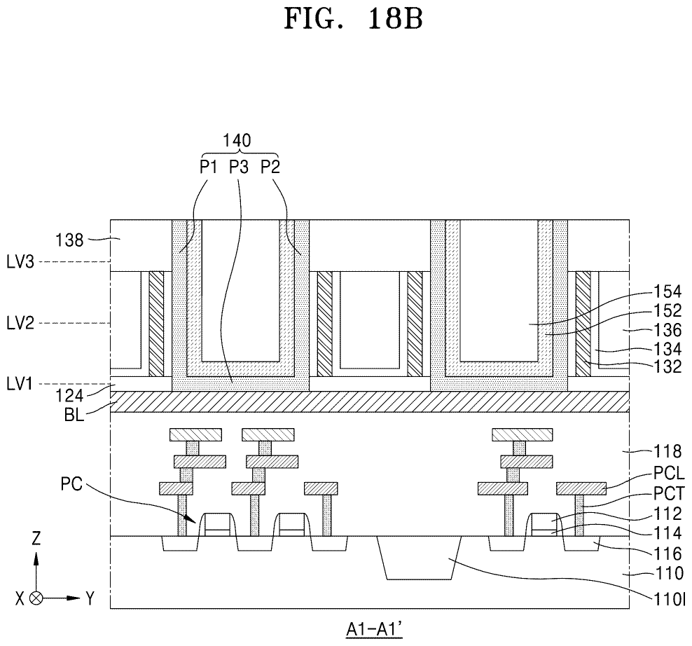

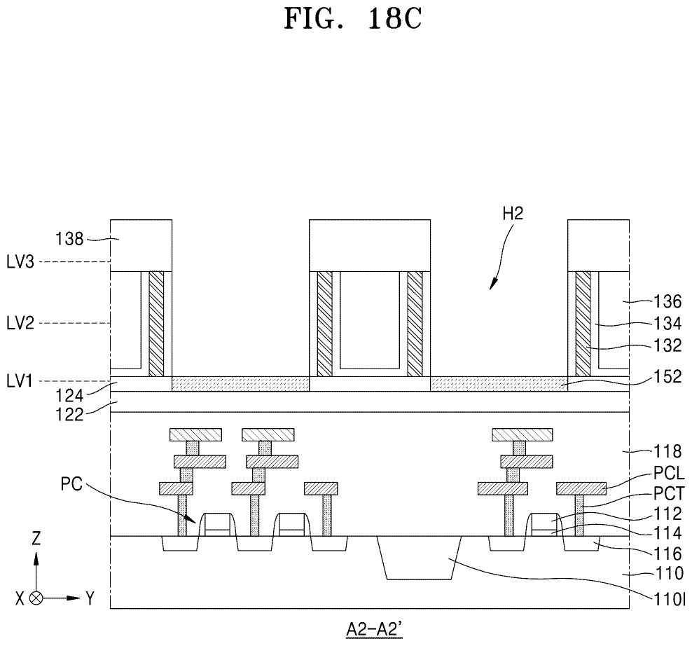

Referring to FIGS. 18A to 18C, a mask pattern may be formed on the first capping liner 152 and the first buried insulating layer 154, and a portion of the first capping liner 152 and a portion of the first buried insulating layer 154 may be removed using the mask pattern as an etching mask, thereby forming a tunnel opening H2.

In some embodiments, the tunnel opening H2 may be located to expose a third side wall S3 and a fourth side wall S4 of the channel layer 140. As the tunnel opening H2 is formed, the first capping liner 152 and the first buried insulating layer 154 may be formed so as to have a width equal to a horizontal-direction width of the first vertical portion P1 of the channel layer 140.

In some embodiments, a portion, which is located at a bottom portion of the tunnel opening H2, of the first capping liner 152 may remain without being removed in a process of forming the tunnel opening H2. Accordingly, side walls of the connection portion P3 of the channel layer 140 may be covered by the first capping liner 152 and may not be exposed in the inner space of the tunnel opening H2.

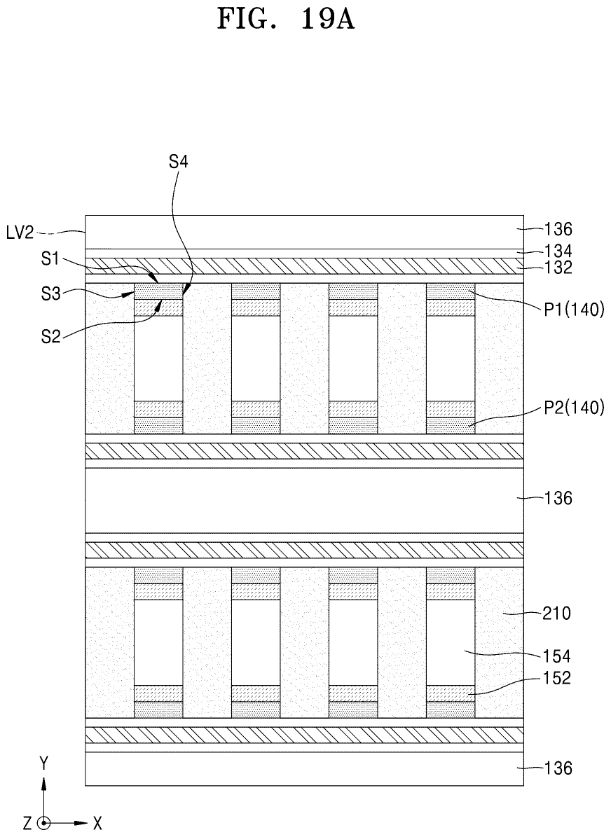

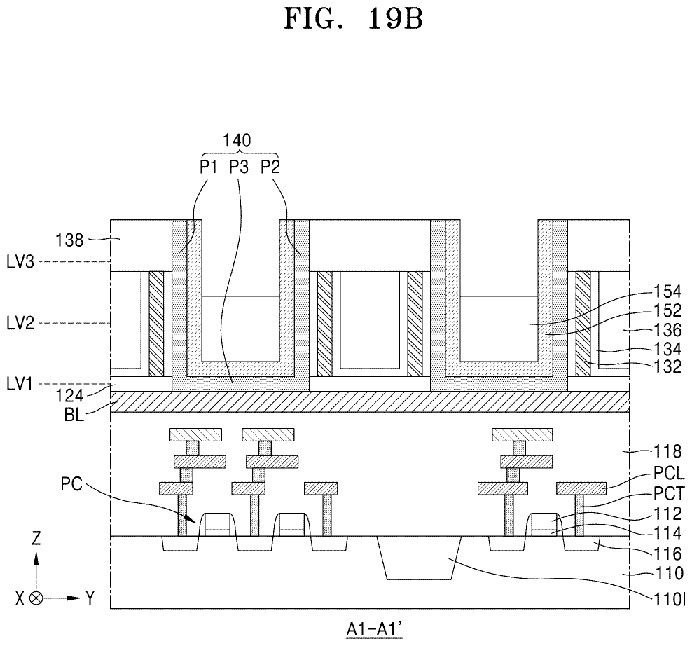

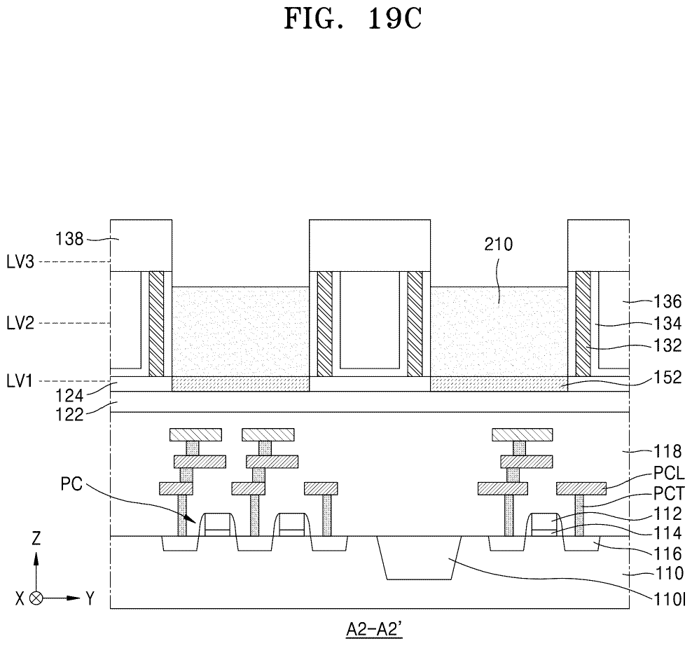

Referring to FIGS. 19A to 19C, an upper portion of the first buried insulating layer 154 may be removed such that the upper surface of the first buried insulating layer 154 is at a lower level than the upper surface of the gate electrode 132 and/or an upper surface of the first capping liner 152.

An oxygen source layer 210 may be formed in the tunnel opening H2. The oxygen source layer 210 may have an upper surface located at the same height as the upper surface of the first buried insulating layer 154. As the oxygen source layer 210 fills the inner space of the tunnel opening H2, the third side wall S3 and the fourth side wall S4 of the first vertical portion P1 of the channel layer 140 may be in contact with the oxygen source layer 210.

In some embodiments, the oxygen source layer 210 may be formed with silicon oxide, using at least one of a CVD process, a low pressure CVD process, a plasma-enhanced CVD process, a MOCVD process, and an atomic layer deposition process.

Thereafter, an annealing process may be performed to a structure in which the oxygen source layer 210 is formed. In some embodiments, the annealing process may be performed at a temperature of about 100° C. to about 400° C. for several minutes to several hours. In some embodiments, the annealing process may be performed at atmospheric pressure or under reduced pressure.

In some embodiments, by the annealing process, oxygen atoms included in the oxygen source layer 210 may diffuse and move into the first vertical portion P1 through a third side wall S3 and a fourth side wall S4 of the first vertical portion P1 of the channel layer 140. Furthermore, by the annealing process, oxygen atoms included in the oxygen source layer 210 may diffuse and move into the second vertical portion P2 through a third side wall S3 and a fourth side wall S4 of the second vertical portion P2 of the channel layer 140.

According to some embodiments, oxygen atoms may diffuse and move from the oxygen source layer 210 filled in the tunnel opening H2 into the channel layer 140 and may thus supplement oxygen atoms into oxygen vacancy within the channel layer 140, thereby decreasing trap density within the channel layer 140.

In addition, the connection portion P3 of the channel layer 140 may be covered by the first capping liner 152 and may not be in contact with the oxygen source layer 210. Accordingly, oxygen may be prevented from being supplied into the connection portion P3 of the channel layer 140 in the annealing process.

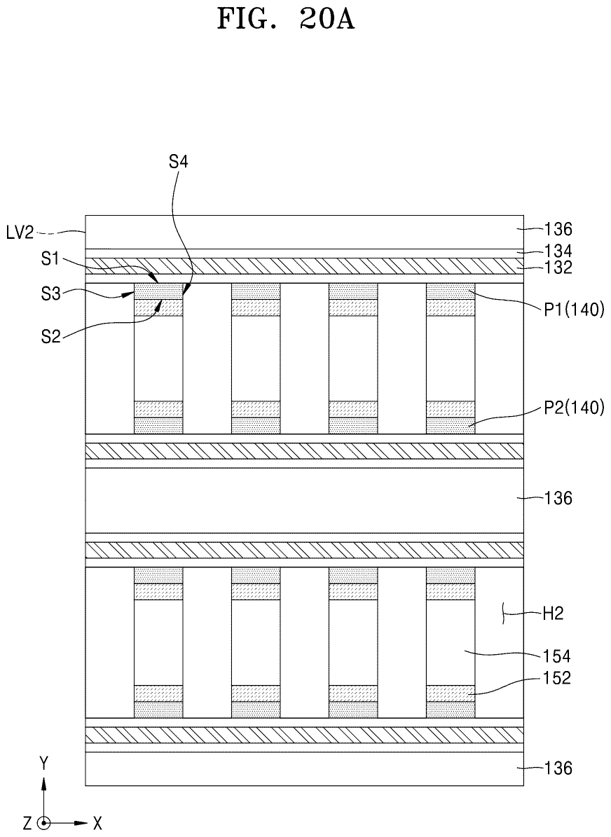

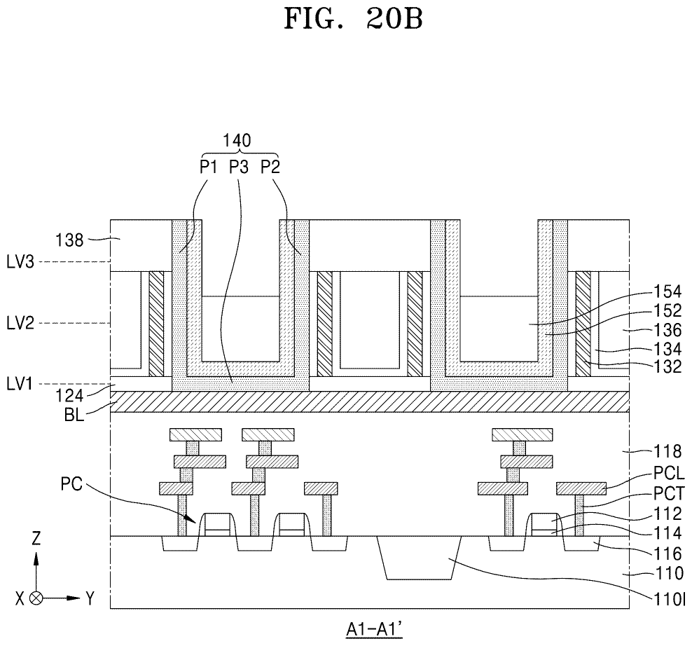

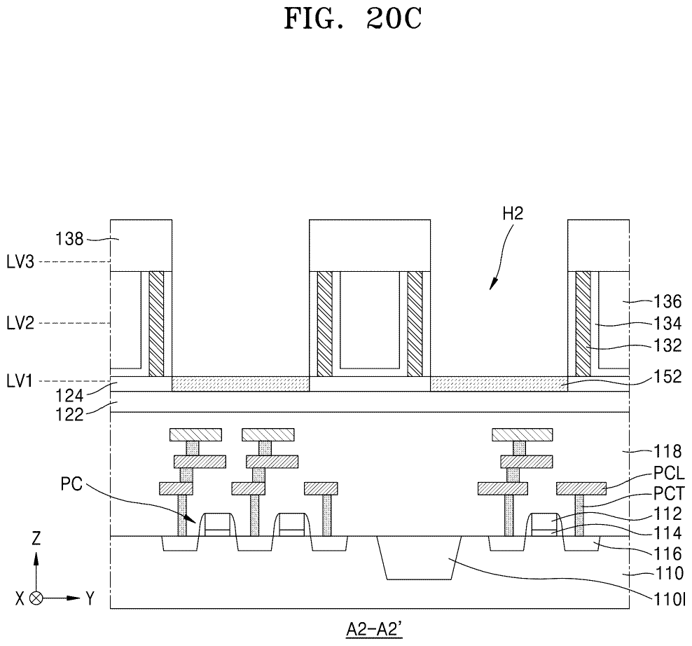

Referring to FIGS. 20A to 20C, the oxygen source layer 210 may be removed and the inner wall of the tunnel opening H2 may be exposed again. For example, the third side wall S3 and the fourth side wall S4 of the channel layer 140, and side walls of the first buried insulating layer 154 which are located on the inner wall of the tunnel opening H2 may be exposed again without being covered by the oxygen source layer 210.

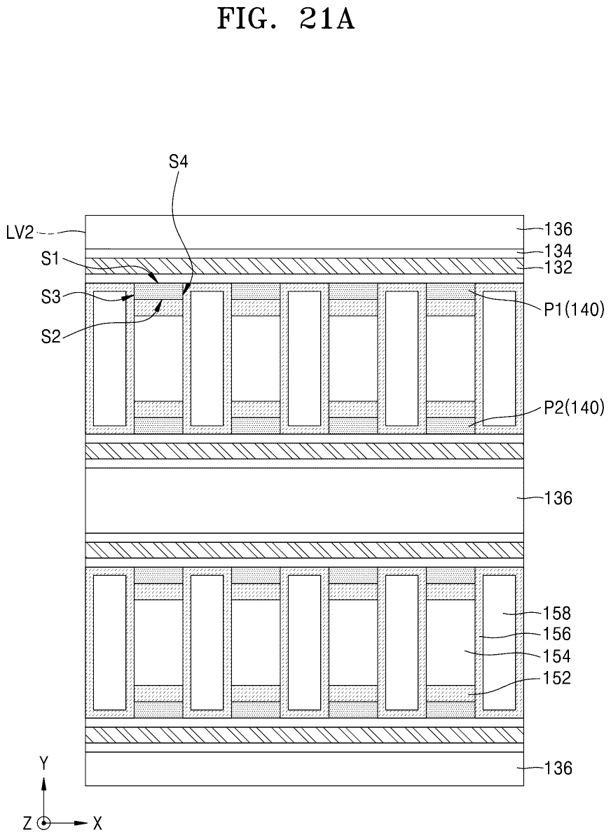

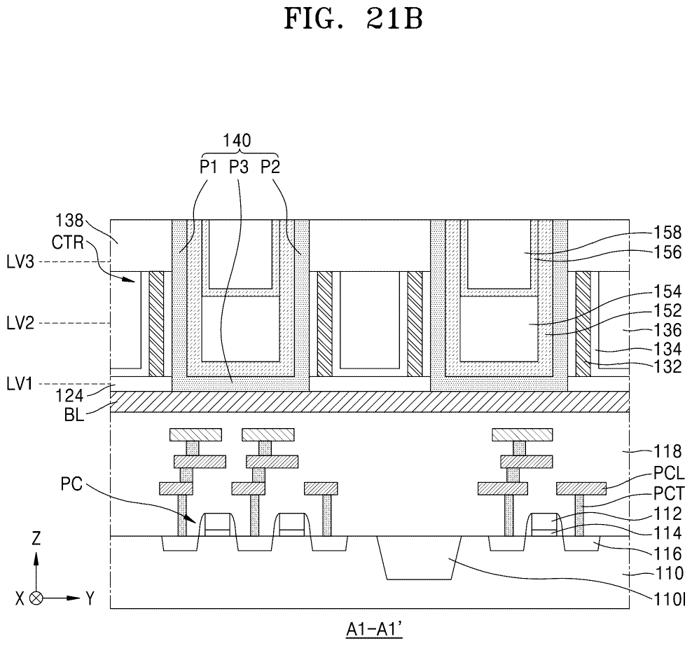

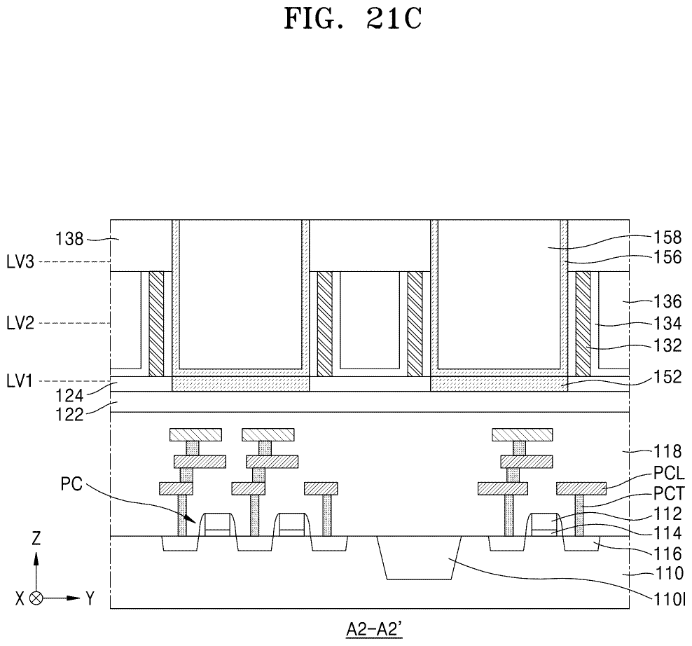

Referring to FIGS. 21A to 21C, a second capping liner 156 and a second buried insulating layer 158 are sequentially formed on the inner wall of the tunnel opening H2. On the inner wall of the tunnel opening H2, the second capping liner 156 may be conformally formed so as to cover the third side wall S3 and the fourth side wall S4 of the channel layer 140 and the side walls of the first buried insulating layer 154.

In some embodiments, the second capping liner 156 may be formed with silicon nitride or a high-k dielectric material, and the second buried insulating layer 158 may be formed with silicon oxide or a low-k dielectric material.

As illustrated in FIG. 21B, the second capping liner 156 may extend onto the upper surface of the first buried insulating layer 154 and the side wall of the first capping liner 152 located at an upper portion of the mold opening H1 (for example, located at a higher level than the upper surface of the first buried insulating layer 154). A lower portion of the second buried insulating layer 158 may fill a space between two adjacent first buried insulating layers 154 (for example, the second buried insulating layer 158 may fill the inner space of the tunnel opening H2), and an upper portion of the second buried insulating layer 158 may extend in the first horizontal direction X at a vertical level higher than the upper surface of the first buried insulating layer 154.

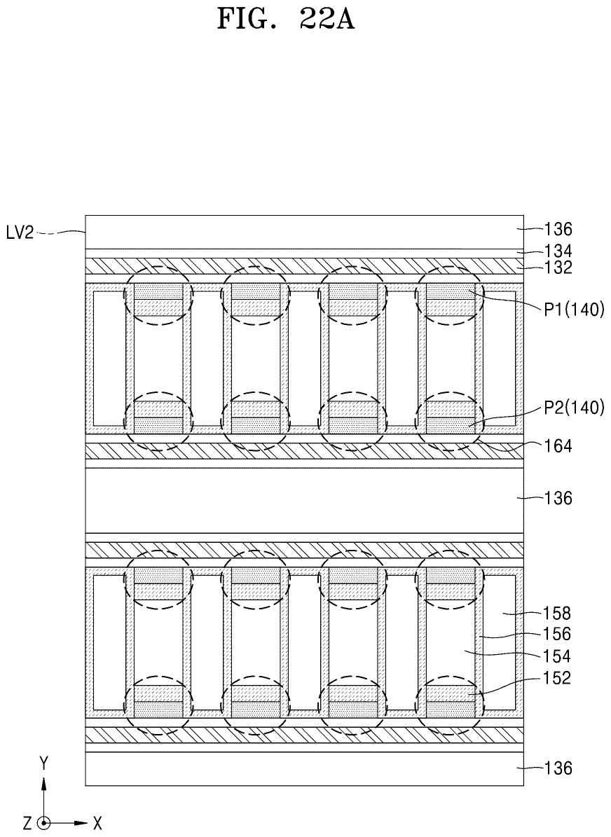

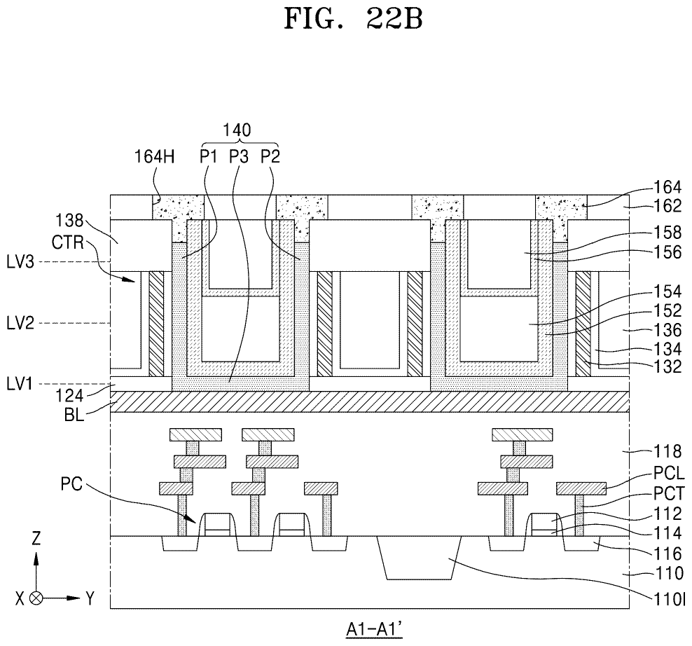

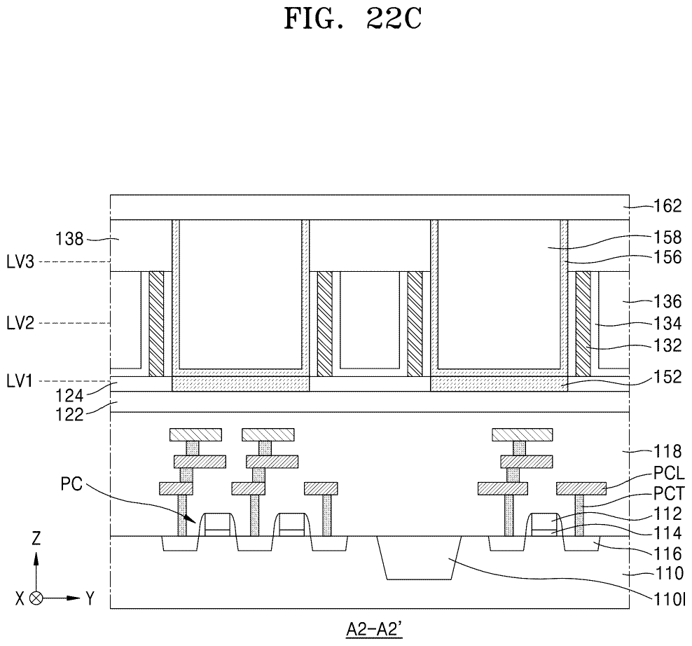

Referring to FIGS. 22A to 22C, an upper insulating layer 162 may be formed on the mold cover layer 138 and the second buried insulating layer 158. Thereafter, a portion of the upper insulating layer 162 may be removed and a landing pad opening 164H exposing the upper surface of the channel layer 140 may be formed. A landing pad 164 may be formed in the landing pad opening 164H. In some embodiments, the landing pad 164 may include or be formed with Ti, TiN, Ta, TaN, W, WN, TiSiN, WSiN, polysilicon, or a combination thereof.

In some embodiments, after forming the landing pad opening 164H, an upper portion of the channel layer 140 (e.g., an upper portion of the first vertical portion P1 and an upper portion of the second vertical portion P2), which is exposed through a bottom portion of the landing pad opening 164H, may be removed and a bottom portion of the landing pad 164 may extend into a space from which the upper portion of the channel layer 140 has been removed. Here, the landing pad 164 may have a T-shaped vertical cross-section.

Referring back to FIGS. 3 and 4, a storage node SN may be formed on the landing pad 164.

The semiconductor device 100 may be completed by performing the process described above, and performing additional steps, such as a cutting process and packaging process to result in semiconductor chips.

According to some embodiments, oxygen atoms may be supplied from the oxygen source layer 210 located in the tunnel opening H2 through the third side wall S3 and the fourth side wall S4 of the channel layer 140 into the channel layer 140. Therefore, trap density within the channel layer 140 may decrease, and the semiconductor device 100 may have excellent electrical properties. Moreover, oxygen supply to the connection portion P3 of the channel layer 140, which is in contact with the bit line BL, may be blocked during annealing, thus improving performance of the cell transistor CTR, for example, increasing on-current.

Furthermore, the second side wall S2 of the channel layer 140 may be covered by the first capping liner 152, and the third side wall S3 and the fourth side wall S4 of the channel layer 140 may be covered by the second capping liner 156. Accordingly, the channel layer 140 may not contact the first buried insulating layer 154 or the second buried insulating layer 158. Therefore, an oxygen path to the channel layer 140 may be blocked when using the semiconductor device 100, and reliability of the cell transistor CTR may be improved.

According to aspects of the inventive concept, side walls of a channel layer may be covered by a first capping liner and a second capping liner, and the channel layer may not contact a first buried insulating layer or a second buried insulating layer. Therefore, an oxygen path to the channel layer may be blocked when using a semiconductor device, and the reliability of a cell transistor may be improved. Furthermore, oxygen supply to a portion of the channel layer, which is in contact with a bit line, may be blocked during annealing, thus improving performance of the cell transistor, for example, increasing on-current.

Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Embodiments described herein will be described referring to plan views and/or cross-sectional views by way of ideal schematic views. Accordingly, the exemplary views may be modified depending on manufacturing technologies and/or tolerances. Therefore, the disclosed embodiments are not limited to those shown in the views, but include modifications in configuration formed on the basis of manufacturing processes. Therefore, regions exemplified in figures may have schematic properties, and shapes of regions shown in figures may exemplify specific shapes of regions of elements to which aspects of the invention are not limited.

Spatially relative terms, such as “beneath,” “below,” “lower,” “above,” “upper,” “top,” “bottom,” and the like, may be used herein for ease of description to describe one element's or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the term “below” can encompass both an orientation of above and below. The device may be otherwise oriented (rotated 90 degrees or at other orientations) and the spatially relative descriptors used herein interpreted accordingly.

Also these spatially relative terms such as “above” and “below” as used herein have their ordinary broad meanings—for example element A can be above element B even if when looking down on the two elements there is no overlap between them (just as something in the sky is generally above something on the ground, even if it is not directly above).

While the inventive concept has been particularly shown and described with reference to embodiments thereof, it will be understood that various changes in form and details may be made therein without departing from the spirit and scope of the following claims.

1. A semiconductor device comprising:
a bit line on a substrate and extending in a first horizontal direction;
a word line disposed at a higher vertical level above a top surface of the substrate than the bit line and extending in a second horizontal direction crossing the first horizontal direction;
a channel layer extending in a vertical direction on a side wall of the word line and including a first side wall facing the word line and a second side wall opposite to the first side wall;
a first capping liner on the second side wall of the channel layer and including silicon nitride or a high-k dielectric material; and
a first buried insulating layer located on a side wall of the first capping liner.

2. The semiconductor device of claim 1, wherein:
the first buried insulating layer is spaced apart from the second side wall of the channel layer in the first horizontal direction, and
the second side wall of the channel layer does not contact the first buried insulating layer.

3. The semiconductor device of claim 1, wherein an upper surface of the first buried insulating layer is at a lower level than an upper surface of the channel layer, with respect to the top surface of the substrate.

4. The semiconductor device of claim 1, wherein:
the channel layer has a first width in the second horizontal direction,
the first capping liner has a second width in the second horizontal direction, and
the second width is equal to the first width.

5. The semiconductor device of claim 4, wherein:
the first buried insulating layer has a third width in the second horizontal direction, and
the third width is equal to the first width.

6. The semiconductor device of claim 1, wherein:
the channel layer further includes a third side wall and a fourth side wall spaced apart from each other in the second horizontal direction, and
the semiconductor device further comprises a second capping liner disposed on the third side wall of the channel layer and a side wall of the first buried insulating layer and including silicon nitride or a high-k dielectric material.

7. The semiconductor device of claim 6, further comprising a second buried insulating layer disposed on the side wall of the first buried insulating layer,
wherein the second capping liner is disposed between the first buried insulating layer and the second buried insulating layer.

8. The semiconductor device of claim 7, wherein each of the first buried insulating layer and the second buried insulating layer include silicon oxide or a low-k dielectric material.

9. The semiconductor device of claim 7, wherein the second capping liner extends onto an upper surface of the first buried insulating layer.

10. The semiconductor device of claim 7, further comprising a gate insulating layer disposed on the side wall of the word line,
wherein:
a first portion of the gate insulating layer is disposed between the word line and the channel layer, and
a second portion of the gate insulating layer is disposed between the word line and the second capping liner.

11. The semiconductor device of claim 1, wherein the channel layer includes at least one of indium gallium zinc oxide (InₓGa_{y}Zn₂O), indium tungsten oxide (InₓW_{y}O), indium tin gallium oxide (InₓSn_{y}Ga_{z}O), indium aluminum zinc oxide (InₓAl_{y}Zn₂O), indium gallium oxide (InₓGa_{y}O), indium tin zinc oxide (InₓSn_{y}Zn₂O), indium gallium silicon oxide (InₓGa_{y}Si_{z}O), indium zinc oxide (InₓZn_{y}O), indium oxide (InₓO), magnesium aluminum zinc oxide (MgₓAl_{y}Zn₂O), zinc tin oxide (ZnₓSn_{y}O), zirconium zinc tin oxide (ZrₓZn_{y}Sn₂O), gallium zinc tin oxide (GaₓZn_{y}Sn₂O), aluminum zinc tin oxide (AlₓZn_{y}Sn_{z}O), and tin oxide (SnₓO).

12. The semiconductor device of claim 1, wherein the channel layer forms part of a vertical channel transistor of a DRAM memory.

13. A semiconductor device comprising:
a bit line disposed on a substrate and extending in a first horizontal direction;
a word line disposed at a higher vertical level above a top surface of the substrate than the bit line and extending in a second horizontal direction crossing the first horizontal direction;
a gate insulating layer disposed on a side wall of the word line;
a channel layer extending in a vertical direction on a side wall of the gate insulating layer to form part of a vertical channel transistor, the channel layer including a first side wall facing the gate insulating layer, a second side wall opposite to the first side wall, and a third side wall and a fourth side wall spaced apart from each other in the second horizontal direction;
a first capping liner disposed on the second side wall of the channel layer and including silicon nitride or a high-k dielectric material; and
a second capping liner disposed on the third side wall and the fourth side wall of the channel layer and including silicon nitride or a high-k dielectric material.

14. The semiconductor device of claim 13, wherein:
a first portion of the gate insulating layer is disposed between the word line and the channel layer, and
a second portion of the gate insulating layer is disposed between the word line and the second capping liner.

15. The semiconductor device of claim 13, further comprising:
a first buried insulating layer disposed on a side wall of the first capping liner, wherein the first capping liner is disposed between the channel layer and the first buried insulating layer; and
a second buried insulating layer disposed on a side wall of the second capping liner.

16. The semiconductor device of claim 15, wherein:
the first buried insulating layer is spaced apart from the second side wall of the channel layer in the first horizontal direction, and
the second side wall of the channel layer does not contact the first buried insulating layer.

17. The semiconductor device of claim 15, wherein:
an upper surface of the first buried insulating layer is at a lower level than an upper surface of the channel layer, with respect to the top surface of the substrate, and
a portion of the second capping liner is disposed on the upper surface of the first buried insulating layer.

18. The semiconductor device of claim 17, wherein:
a portion of the second buried insulating layer is disposed on the portion of the second capping liner, and
the second capping liner is disposed between the second buried insulating layer and the first buried insulating layer.

19. A semiconductor device comprising:
a peripheral circuit region disposed on a substrate;
a bit line disposed on the peripheral circuit region and extending in a first horizontal direction;
a word line disposed at a higher vertical level above a top surface of the substrate than the bit line and extending in a second horizontal direction crossing the first horizontal direction;
a channel layer extending in a vertical direction on a side wall of the word line and including a first side wall facing the word line, a second side wall opposite to the first side wall, and a third side wall and a fourth side wall spaced apart from each other in the second horizontal direction;
a first capping liner disposed on the second side wall of the channel layer and including silicon nitride or a high-k dielectric material;
a first buried insulating layer disposed on a side wall of the first capping liner;
a second capping liner disposed on the third side wall of the channel layer and a side wall of the first buried insulating layer and including silicon nitride or a high-k dielectric material; and
a second buried insulating layer disposed on the side wall of the first buried insulating layer, wherein the second capping liner is disposed between the first buried insulating layer and the second buried insulating layer.

20. The semiconductor device of claim 19, wherein the first buried insulating layer and the second buried insulating layer each include silicon oxide or a low-k dielectric material.

21. (canceled)
